(19) United States
(12) Patent Application Publication
(10) Pub. No.: US 2015/0090977 A1
(43) Pub. Date: Apr. 2, 2015

(54) ORGANIC ELECTROLUMINESCENCE UNIT, METHOD OF MANUFACTURING ORGANIC ELECTROLUMINESCENCE UNIT, AND ELECTRONIC APPARATUS

(71) Applicant: SONY CORPORATION, Tokyo (JP)

(72) Inventors: Toshiaki Imai, Kanagawa (JP); Kazunari Takagi, Tokyo (JP); Tadahiko Yoshinaga, Kanagawa (JP); Tatsuya Matsumi, Kanagawa (JP); Makoto Ando, Tokyo (JP)

(21) Appl. No.: 14/394,695

(22) PCT Filed: Apr. 11, 2013
(86) PCT No.: PCT/JP2013/061435

§ 371 Date: Oct. 15, 2014

(30) Foreign Application Priority Data
Apr. 23, 2012 (JP) 2012-097626

(51) Int. Cl. H01L 27/32; H01L 51/50; H01L 51/00; H01L 51/56

(52) U.S. Cl. CPC H01L 27/3211; H01L 51/56; H01L 51/5056; H01L 51/0004; H01L 51/504
USPC 257/40; 438/35

(57) ABSTRACT

An organic electroluminescence unit includes: a plurality of light-emitting layers of different colors (14R, 14G, 14B); a first electrode (11) and a second electrode (16) applying a voltage to each of the plurality of light-emitting layers; and a charge transport layer disposed between one or more light-emitting layers of the plurality of light-emitting layers and the first electrode (11).

### TECHNICAL FIELD

The present disclosure relates to an organic electroluminescence unit emitting light with use of an organic electroluminescence (EL) phenomenon, a method of manufacturing the same, and an electronic apparatus including the organic electroluminescence unit.

### BACKGROUND ART

Display devices with higher performance are desired along with acceleration of development of information and communication industry. Specially, organic EL devices have been attracting attention as next generation display devices, and the organic EL devices have advantages, as self-emitting type display devices, of not only a wide viewing angle and excellent contrast but also fast response speed.

The organic EL devices have a configuration in which a plurality of layers including a light-emitting layer are laminated. These layers are formed by, for example, a dry process such as a vacuum deposition method. More specifically, in a typical dry process, a mask with an opening is sandwiched between an evaporation source and a substrate to pattern a layer into a desired shape. When display units using such an organic EL device are upsized or have higher definition, alignment becomes difficult and an aperture ratio is reduced because of deformation of the mask, complicated transportation, and the like. Accordingly, there is an issue that device characteristics decline.

On the contrary, for example, in PTL 1, there is disclosed a laser transfer method in which a transfer layer (an organic film) is formed on a donor film having a protruding portion and a recessed portion, and then the organic film located on the protruding portion of the donor film is transferred with use of a laser. However, in this technique, since the organic film is formed on the protruding portion and the recessed portion, there is an issue that it is difficult to maintain uniformity of a film thickness of the organic film.

Therefore, in PTL 2, there is disclosed a letterpress reverse offset printing method (hereinafter simply referred to as reverse printing method) using a blanket. In the reverse printing method, the blanket is coated with an ink including a light-emitting material to form an ink layer, and then an unnecessary region (a non-printing pattern) of the ink layer is selectively removed with use of an engraved plate. Thus, a printing pattern on the blanket is transferred to a printing substrate to form a light-emitting layer. In this reverse printing method, since an organic film is formed on a flat blanket, an organic film with a uniform film thickness is easily formed.

### CITATION LIST

### Patent Literature

PTL 1: Japanese Unexamined Patent Application Publication No. 2006-216563
[PTL 2] PTL 2: Japanese Unexamined Patent Application Publication No. 2004-186111

### SUMMARY

However, in the reverse printing method, since an ink applied to the blanket is absorbed, a pigment may remain in a region where the non-printing pattern has been removed by contact with the engraved plate. In a display unit having a plurality of color pixels, there is an issue that this remaining pigment is adhered to a pixel region of a different color to cause color mixture in emission light, thereby resulting in a decline in color purity.

It is desirable to provide an organic electroluminescence unit capable of suppressing a decline in color purity, a method of manufacturing an organic electroluminescence unit, and an electronic apparatus.

According to an embodiment of the disclosure, there is provided an organic electroluminescence unit including: a plurality of light-emitting layers of different colors; a first electrode and a second electrode applying a voltage to each of the plurality of light-emitting layers; and a charge transport layer disposed between one or more light-emitting layers of the plurality of light-emitting layers and the first electrode.

In the organic electroluminescence unit according to the embodiment of the disclosure, the charge transport layer is disposed between one light-emitting layer of the light-emitting layers of different colors and the first electrode to suppress color mixture in emission light.

According to an embodiment of the disclosure, there is provided a method of manufacturing an organic electroluminescence unit including: forming a first electrode; forming a plurality of light-emitting layers of different colors on the first electrode; and forming a second electrode on the plurality of light-emitting layers, in which in the forming of the light-emitting layers, one of the plurality of light-emitting layers is formed, and then a charge transport layer is formed between one or more other light-emitting layers and the first electrode.

In the method of manufacturing the organic electroluminescence unit according to the embodiment of the disclosure, in the forming of the light-emitting layers, after one light-emitting layer of the plurality of light-emitting layers is formed, the charge transport layer is formed between one other light-emitting layer and the first electrode. Therefore, color mixture in emission light in a device having the other light-emitting layer is suppressed.

According to an embodiment of the disclosure, there is provided an electronic apparatus including an organic electroluminescence unit, the organic electroluminescence unit including: a plurality of light-emitting layers of different colors; a first electrode and a second electrode applying a voltage to each of the plurality of light-emitting layers; and a charge transport layer disposed between one or more light-emitting layers of the plurality of light-emitting layers and the first electrode.

In the organic electroluminescence unit and the method of manufacturing the organic electroluminescence unit according to the embodiments of the disclosure, after one light-emitting layer of the light-emitting layers of different colors is formed, the charge transport layer is formed between one other light-emitting layer and the first electrode. Therefore, color mixture in light emission from a device having the other light-emitting layer is suppressed, and a decline in color purity is allowed to be suppressed accordingly.

It is to be understood that both the foregoing general description and the following detailed description are exemplary, and are intended to provide further explanation of the technology as claimed.

### BRIEF DESCRIPTION OF DRAWINGS

FIG. 1 is a sectional view illustrating a configuration of a display unit according to a first embodiment of the disclosure.

FIG. 2 is a schematic view illustrating a circuit configuration example of a drive substrate of the display unit illustrated in FIG. 1.

FIG. 3 is an equivalent circuit diagram illustrating an example of a pixel circuit of the display unit illustrated in FIG. 1.

FIG. 4 is a sectional view illustrating a configuration example of the drive substrate illustrated in FIG. 1.

FIG. 5 is a schematic sectional view illustrating a specific configuration of an organic EL device illustrated in FIG. 1.

FIG. 6A and FIG. 6B are sectional views for describing a method of manufacturing the display unit illustrated in FIG. 1.

FIG. 7 is a sectional view illustrating a process following FIGS. 6A and 6B.

FIG. 8 is a sectional view illustrating a process (a process of forming light-emitting layers of R and G) following FIG. 7.

FIGS. 9A to 9C are schematic views for describing a specific procedure of the process illustrated in FIG. 7.

FIGS. 10A to 10C are schematic views illustrating a process following FIGS. 9A to 9C.

FIGS. 11A to 11C are schematic views illustrating a process following FIGS. 10A and 10C.

FIGS. 12A to 12C are schematic views illustrating a process following FIGS. 11A to 11C.

FIGS. 13A to 13C are schematic views illustrating a process following FIGS. 12A to 12C.

FIGS. 14A and 14B are schematic sectional views illustrating specific configurations of the device substrate after the light-emitting layer of R is formed and the device substrate after the light-emitting layer of G is formed, respectively.

FIGS. 15A and 15B are schematic views describing light emission principles in a comparative example and the embodiment, respectively.

FIGS. 16A and 16B are schematic views illustrating an emission spectrum of a G device in the comparative example and an emission spectrum of a G device in the embodiment, respectively.

FIGS. 17A and 17B are sectional views illustrating a process (a process of forming a light-emitting layer of B) following FIG. 8.

FIG. 18 is a sectional view illustrating a process following FIGS. 17A and 17B.

FIG. 19 is a sectional view illustrating a specific configuration of an organic EL device in a display unit according to a second embodiment of the disclosure.

FIG. 20 is a sectional view illustrating a specific configuration of an organic EL device in a display unit according to a third embodiment of the disclosure.

FIGS. 21A to 21E are process diagrams illustrating a process of forming a charge transport layer and a green light-emitting layer of the organic EL device illustrated in FIG. 20.

FIG. 22 is a sectional view illustrating a specific configuration of an organic EL device according to Modification 1.

FIGS. 23A and 23B are perspective views illustrating a configuration of a smartphone using the display unit.

FIG. 24 is a perspective view illustrating a configuration of a television using the display unit.

FIGS. 25A and 25B are perspective views illustrating a configuration of a digital still camera using the display unit.

FIG. 26 is a perspective view illustrating an appearance of a personal computer using the display unit.

FIG. 27 is a perspective view illustrating an appearance of a video camera using the display unit.

FIG. 28 is a plan view illustrating a configuration of a cellular phone using the display unit.

### DESCRIPTION OF EMBODIMENTS

Embodiments of the present disclosure will be described in detail below referring to the accompanying drawings. It is to be noted that description will be given in the following order.

1. First Embodiment (An example in which a first light-emitting layer is formed, and then a charge transport layer and a second light-emitting layer are formed in this order on a second organic EL device)
1-1. Entire configuration
1-2. Manufacturing method

2. Second Embodiment (An example in which the first light-emitting layer is formed, and then the charge transport layer is formed as a layer common to devices)

3. Third Embodiment (An example in which the first light-emitting layer is formed, and then the charge transport layer and the second light-emitting layer are concurrently formed on the second organic EL device)

4. Modification (An example of a display unit including a yellow light-emitting layer and a blue light-emitting layer)

5. Application Examples (Examples of an electronic apparatus)

### First Embodiment

### 1-1. Entire Configuration

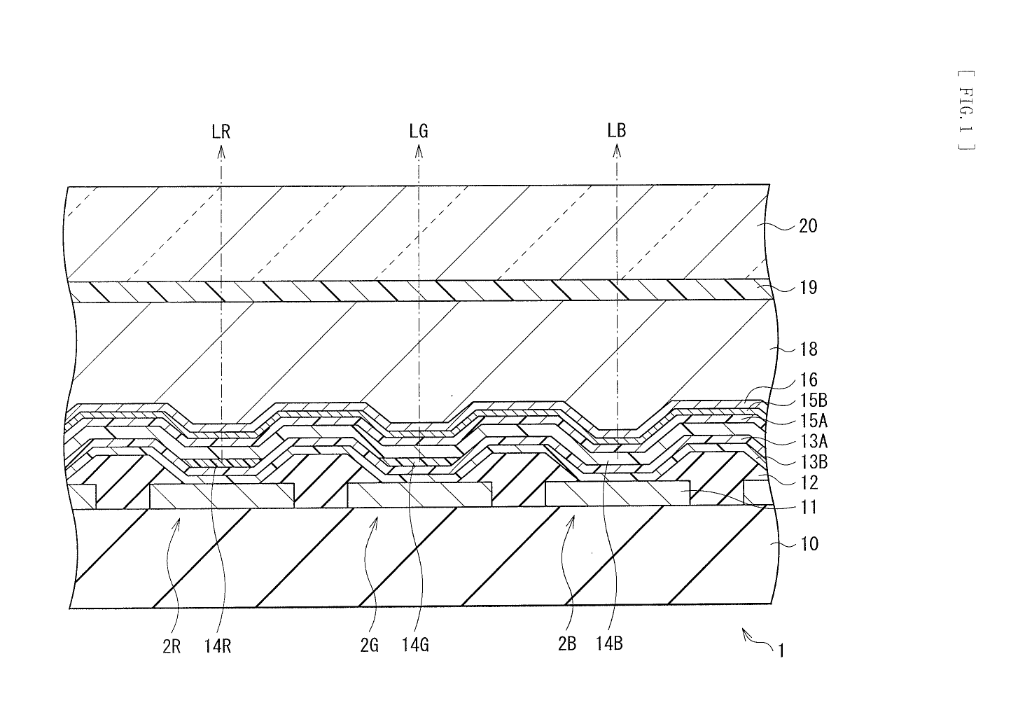

FIG. 1 illustrates a sectional configuration of an organic electroluminescence unit (a display unit 1) according to a first embodiment of the disclosure. The display unit 1 is used as, for example, an organic electroluminescence color display, and has a configuration in which a plurality of organic EL devices 2R (first organic EL devices, red pixels) emitting red light, a plurality of organic EL devices 2G (second organic EL devices, green pixels) emitting green light, and a plurality of organic EL devices 2B (blue pixels) emitting blue light are regularly arranged. These organic EL devices 2 (2R, 2G, and 2B) are covered with a protective layer 18, and are sealed by a sealing substrate 20 with an adhesive layer 19 in between. The display unit 1 is a top emission type display unit in which a combination of the organic EL devices 2R, 2G, and 2B adjacent to one another configures one pixel, and emits light LR, LG, and LB of three colors from a top surface of the sealing substrate 20. Respective components will be described in detail below.

### (Drive Substrate 10)

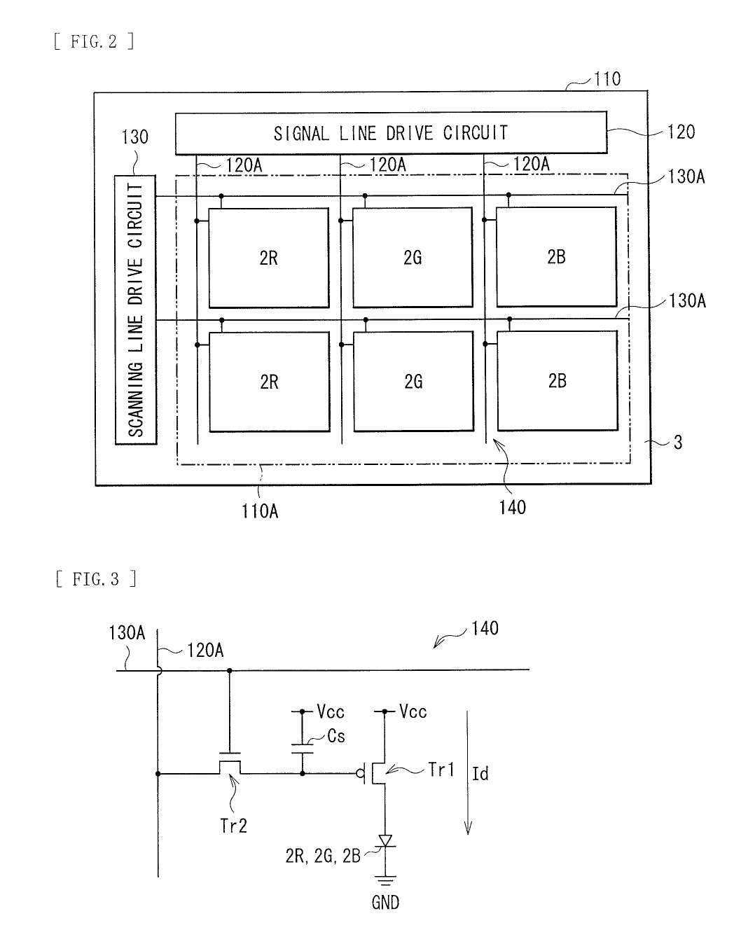

FIG. 2 illustrates a circuit configuration formed on the drive substrate 10 of the display unit 1 together with the above-described organic EL devices 2R, 2G, and 2B. In the drive substrate 10, for example, a display region 110A where the plurality of organic EL devices 2R, 2G, and 2B are arranged in a matrix form is formed on a substrate 110, and a signal line drive circuit 120 and a scanning line drive circuit 130 as drivers for image display are disposed around the display region 110A. A plurality of signal lines 120A extending in a column direction are connected to the signal line drive circuit 120, and a plurality of scanning lines 130A extending in a row direction are connected to the scanning line drive circuit 130. An intersection of each signal line 120A and each scanning line 130A corresponds to one of the organic LE devices 2R, 2G, and 2B. In addition to these circuits, a power source line drive circuit (not illustrated) is disposed in a region around the display region 110A.

FIG. 3 illustrates an example of a pixel circuit 140 disposed in the display region 110A. The pixel circuit 140 includes, for example, a driving transistor Tr1 and a writing transistor Tr2 (each corresponding to a TFT 111 which will be described later), a capacitor (a retention capacitor) Cs between these transistors Tr1 and Tr2, and the organic EL device 2R, 2G, or 2B connected to the driving transistor Tr1 in series between a first power source line (Vcc) and a second power source line (GND). The driving transistor Tr1 and the writing transistor Tr2 each are configured of a typical thin film transistor (TFT), and the TFT may have, for example, an inverted stagger configuration (a so-called bottom gate type) or a stagger configuration (a top gate type). With such a configuration, an image signal is supplied from the signal line drive circuit 120 to a source (or a drain) of the writing transistor Tr2 through the signal line 120A. A scanning signal is supplied from the scanning line drive circuit 130 to a gate of the writing transistor Tr2 through the scanning line 130A.

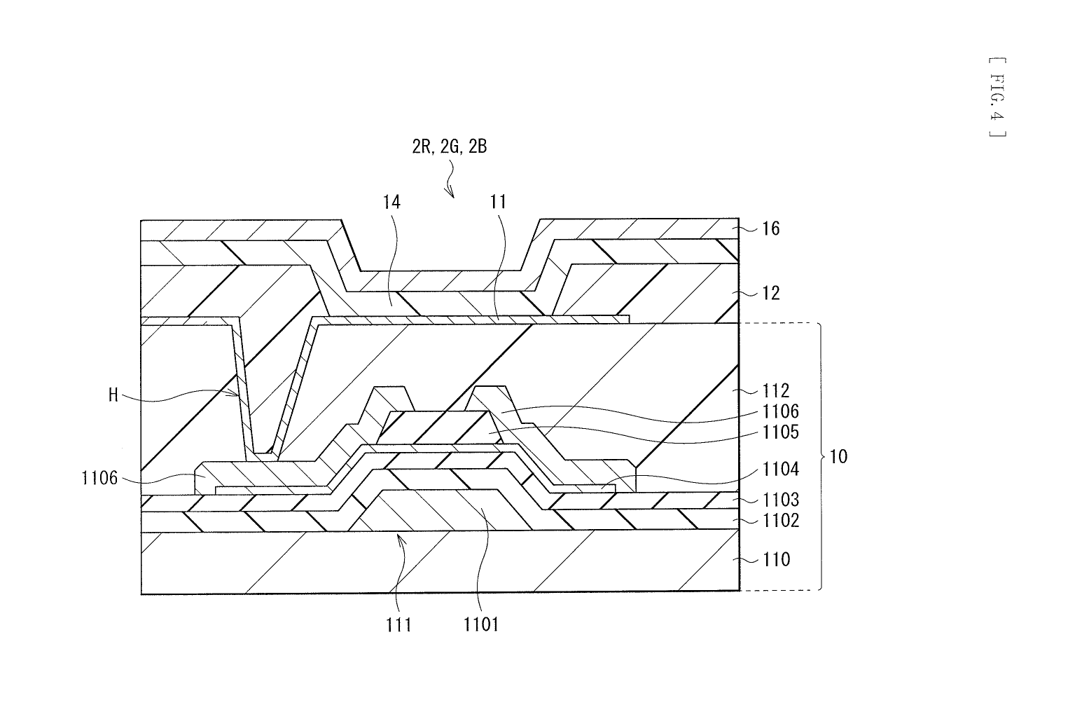

FIG. 4 illustrates a specific sectional configuration of the drive substrate 10 (a configuration of the TFT 111) together with a schematic configuration of the organic EL device 2R, 2G, or 2B. In the drive substrate 10, the TFT 111 corresponding to each of the above-described driving transistor Tr1 and the above-described transistor Tr2 is formed. In the TFT 111, for example, a gate electrode 1101 is disposed in a selective region on the substrate 110, and a semiconductor layer 1104 is formed on the gate electrode 1101 with gate insulating films 1102 and 1103 in between. A channel protective film 1105 is disposed on a region serving as a channel of the semiconductor layer 1104 (a region facing the gate electrode 1101). A pair of source and drain electrodes 1106 are electrically connected to the semiconductor layer 1104. A planarization layer 112 is formed on an entire surface of the substrate 110 to cover such a TFT 111.

The substrate 110 is configured of, for example, a glass substrate or a plastic substrate. Alternatively, the substrate 110 may be made of quartz, silicon, metal or the like with a surface subjected to insulation treatment. Moreover, the substrate 110 may have flexibility or rigidity.

The gate electrode 1101 has a function of controlling carrier density in the semiconductor layer 1104 by a gate voltage applied to the TFT 111. The gate electrode 1101 is configured of, for example, a single-layer film made of one kind selected from a group configured of Mo, Al, an aluminum alloy, and the like, or a laminate film made of two or more kinds selected from the group. Examples of the aluminum alloy include an aluminum-neodymium alloy.

The gate insulating films 1102 and 1103 each are configured of, for example, a single-layer film made of one kind selected from a group configured of silicon oxide (SiO_{X}), silicon nitride (SiN_{X}), silicon nitride oxide (SiON), aluminum oxide (Al₂O₂), and the like, or a laminate film made of two or more kind selected from the group. In this case, the gate insulating film 1102 is made of, for example, SiO₂, and the gate insulating film 1103 is made of, for example, Si₃N₄. A total film thickness of the gate insulating films 1102 and 1103 is, for example, within a range of about 200 nm to about 300 nm both inclusive.

The semiconductor layer 1104 is made of, for example, an oxide semiconductor including, as a main component, an oxide of one or more kinds selected from a group configured of indium (In), gallium (Ga), zinc (Zn), tin (Sn), Al, and Ti. The semiconductor layer 1104 forms a channel between the pair of source and drain electrodes 1106 by application of a gate voltage. A film thickness of the semiconductor layer 1104 is preferably enough not to cause degradation in ON-current of a thin-film transistor, thereby allowing an influence of a negative charge which will be described later to be exerted on the channel. More specifically, the film thickness of the semiconductor layer 1104 is preferably within a range of about 5 nm to about 100 nm both inclusive.

The channel protective film 1105 is formed on the semiconductor layer 1104, and prevents damage to the channel when the source and drain electrodes 1106 are formed. The channel protective film 1105 is configured of, for example, an insulating film including silicon (Si), oxygen (O₂), and fluorine (F) with a thickness of, for example, about 10 nm to about 300 nm both inclusive.

The source and drain electrodes 1106 function as a source and a drain, and each are configured of a single-layer film made of one kind selected from a group configured of molybdenum (Mo), aluminum (Al), copper (Cu), titanium, ITO, titanium oxide (TiO), and the like, or a laminate film made of two or more kinds selected from the group. For example, a three-layer film configured through laminating Mo with a thickness of about 50 nm, Al with a thickness of about 500 nm, and Mo with a thickness of about 50 nm in this order, or a metal or a metal compound having a weak link to oxygen such as a metal compound including oxygen, for example, ITO or titanium oxide is preferably used. Therefore, electrical characteristics of an oxide semiconductor are allowed to be stably maintained.

The planarization layer 112 is made of, for example, an organic material such as polyimide or novolac. A thickness of the planarization layer 112 is, for example, within a range of about 10 nm to about 100 nm both inclusive, and is preferably about 50 nm or less. First electrodes 11 of the organic EL devices 2 are formed on the planarization layer 112.

It is to be noted that a contact hole H is formed in the planarization layer 112, and the source or drain electrode 1106 and the first electrode 11 of each of the organic EL devices 2R, 2G, and 2B are electrically connected to each other through the contact hole H. The first electrodes 11 for respective pixels are electrically separated from one another by an insulating film 12, and an organic layer 14 including a light-emitting layer of each color which will be described later and a second electrode 16 are laminated on the first electrodes 11. Specific configurations of the organic EL devices 2R, 2G, and 2B will be described later.

The protective layer 18 prevents entry of water into the organic EL devices 2R, 2G, and 2B, and is made of a material with low transparency and low water permeability with a thickness of, for example, about 2 μm to about 3 μm both inclusive. The protective layer 18 may be made of an insulating material or a conductive material. As the insulating material, an inorganic amorphous insulating material, for example, amorphous silicon (α-Si), amorphous silicon carbide (α-SiC), amorphous silicon nitride (α-Si₁₋ₓNₓ), amorphous carbon (α-C), or the like is used. Such an inorganic amorphous insulating material does not form grains; therefore, the inorganic amorphous insulating material forms a favorable protective film with low water permeability.

The sealing substrate 20 seals the organic EL devices 2R, 2G, and 2B together with the adhesive layer 19. The sealing substrate 20 is made of a material transparent to light emitted from the organic EL devices 2 such as glass. In the sealing substrate 20, for example, a color filter and a black matrix (both not illustrated) may be included, and in this case, the sealing substrate 20 extracts each color light emitted from each of the organic EL devices 2R, 2G, and 2B and absorbs external light reflected by the organic EL devices 2R, 2G, and 2B, thereby improving contrast.

### (Organic EL Devices 2R, 2G, and 2B)

The organic EL devices 2R, 2G, and 2B have a top emission type device configuration. However, the organic EL devices 2R, 2G, and 2B are not limited to the configuration, and may have, for example, a transmissive type device configuration, that is, a bottom emission type device configuration extracting light from the substrate 110.

Each of the organic EL devices 2R is formed in an opening section of the insulating film 12, and has, for example, a laminate configuration in which a hole injection layer (HIL) 13B, a hole transport layer (HTL) 13A, a red light-emitting layer 14R, a blue light-emitting layer 14B, and an electron transport layer (ETL) 15A, an electron injection layer (EIL) 15B, and the second electrode 16 are laminated in this order on the first electrode 11. Likewise, each of the organic EL devices 2G has, for example, a laminate configuration similar to the laminate configuration of the organic EL device 2R, except that a green light-emitting layer 14G is included instead of the red light-emitting layer 14G. Each of the organic EL devices 2B has, for example, a laminate configuration in which the hole injection layer 13B, the hole transport layer 13A, the blue light-emitting layer 14B, the electron transport layer 15A, the electron injection layer 15B, and the second electrode 16 are laminated in this order on the first electrode 11. Thus, in the embodiment, the red light-emitting layer 14R and the green light-emitting layer 14G are formed separately for each pixel, and the blue light-emitting layer 14B is formed common to all pixels on the entire display region 110A. The hole injection layer 13B, the hole transport layer 13A, the electron transport layer 15A, and the electron injection layer 15B are formed common to all pixels. As will be described in detail later, in the embodiment, the red light-emitting layer 14R and the green light-emitting layer 14G are formed by a reverse printing method, and the blue light-emitting layer 14B is formed by a vacuum deposition method. Moreover, although not illustrated herein, the organic EL devices 2G of green further include a charge transport layer 17 formed during printing of the light-emitting layer.

The first electrode 11 functions as, for example, an anode, and is made of, for example, a high reflective material such as aluminum, titanium, or chromium (Cr) in the case where the display unit 1 is of a top emission type. It is to be noted that, in the case where the display unit 1 is of a bottom emission type, for example, a transparent conductive film made of ITO, IZO, IGZO, or the like is used.

The insulating film 12 allows the organic EL devices 2R, 2G, and 2B to be electrically insulated from one another, and partitions a light emission region into light emission sub-regions corresponding to respective pixels. A plurality of opening sections are included in the insulating film 12, and one of the organic EL devices 2R, 2G, and 2B is formed in each of the opening sections. The insulating film 12 is made of, for example, an organic material such as polyimide, a novolac resin, or an acrylic resin. Alternatively, the insulating film 12 may be configured through laminating an organic material and an inorganic material. Examples of the inorganic material include SiO₂, SiO, SiC, and SiN.

The hole injection layer 13B is a buffer layer for enhancing hole injection efficiency and preventing leakage. The hole injection layer 13B preferably has a thickness of, for example, about 5 nm to about 200 nm both inclusive, and more preferably about 8 nm to about 150 nm both inclusive. A material of the hole injection layer 13B may be appropriately selected in relation to a material of an adjacent layer such as an electrode, and examples of the material of the hole injection layer 13B include polyaniline, polythiophene, polypyrrole, polyphenylene vinylene, polythienylene vinylene, polyquinoline, polyquinoxaline, and derivatives thereof, a conductive polymer such as a polymer including an aromatic amine structure in a main chain or a side chain, metal phthalocyanine (such as copper phthalocyanine), and carbon. Specific examples of the conductive polymer include oligoaniline, and polydioxythiophene such as poly(3,4-ethylenedioxythiophene) (PEDOT). In addition, Nation (trademark) and Liquion (trademark) available from H.C. Starck GmbH, ELsource (trademark) available from Nissan Chemical Industries. Ltd., a conductive polymer called Verazol (trademark) available from Soken Chemical & Engineering Co., Ltd. or the like may be used.

The hole transport layer 13A enhances hole transport efficiency to the light-emitting layers of respective colors. For example, a thickness of the hole transport layer 13A depends on an entire device configuration, but is preferably within a range of about 5 nm to about 200 nm both inclusive, and is more preferably within a range of about 8 nm to about 150 nm both inclusive. The hole transport layer 13A is made of a polymer material soluble in a solvent, for example, polybinylcarbazole, polyfluorene, polyaniline, polysilane, or a derivative thereof, a polysiloxane derivative having an aromatic amine in a side chain or a main chain, polythiophene or a derivative thereof, polypyrrole, or 4,4′-bis(N-1-naphthyl-N-phenylamino)biphenyl (α-NPD).

The red light-emitting layer 14R, the green light-emitting layer 14G, and the blue light-emitting layer 14B emit light by the recombination of electrons and holes in response to the application of an electric field. For example, a thickness of each of these light-emitting layers of respective colors depends on the entire device configuration, but is preferably within a range of about 10 nm to about 200 nm both inclusive, and is more preferably within a range of about 20 nm to about 150 nm both inclusive.

The red light-emitting layer 14R, the green light-emitting layer 14G, and the blue light-emitting layer 14B may be made of materials corresponding to respective colors of emission light, and a polymer material (with a molecular weight of, for example, about 5000 or over) or a low-molecular material (with a molecular weight of, for example, about 5000 or less) may be used. When the low-molecular material is used, for example, a mixture material including two or more kinds, that is, a host material and a dopant material may be used. When the polymer material is used, for example, the polymer material is used in a state of an ink dissolved in an organic solvent. Moreover, a mixture material including the low-molecular material and the polymer material may be used.

In the embodiment, as described above, the red light-emitting layer 14R and the green light-emitting layer 14G are formed by a reverse printing method which is a so-called wet process, and the blue light-emitting layer 14B is formed by a vacuum deposition method which is a dry process. Therefore, as the materials of the red light-emitting layer 14R and the green light-emitting layer 14G, the polymer material is mainly used, and in the blue light-emitting layer 14B, the low-molecular material is mainly used.

Examples of the polymer material include a polyfluorene-based polymer derivative, a (poly)paraphenylene vinylene derivative, a polyphenylene derivative, a polyvinylcarbazole derivative, a polythiophene derivative, a perylene-based pigment, a coumarin-based pigment, a rhodamine-based pigment, and the above-described polymer materials doped with a dopant material. Examples of the dopant material include rubrene, perylene, 9,10-diphenylanthracene, tetraphenyl butadiene, nile red, and Coumarin6. Examples of the low-molecular material include benzene, styrylamine, triphenylamine, porphyrin, triphenylene, azatriphenylene, tetracyanoquinodimethane, triazole, imidazole, oxadiazole, polyarylalkane, phenylenediamine, arylamine, oxazole, anthracene, fluorenone, hydrazone, stilbene, and derivatives thereof, and heterocyclic conjugated system monomers and oligomers such as a polysilane-based compound, a vinylcarbazole-based compound, a thiophene-based compound, and an aniline-based compound. Moreover, each of the light-emitting layers of respective colors may include, as a guest material, a material with high light emission efficiency, for example, a low-molecular fluorescent material, a phosphorescent pigment, or a metal complex in addition to these materials.

The electron transport layer 15A enhances electron transport efficiency to the light-emitting layers of respective colors. Examples of a material of the electron transport layer 15A include quinoline, perylene, phenanthroline, bisstyryl, pyrazine, triazole, oxazole, fullerene, oxadiazole, fluorenone, derivatives thereof, and metal complexes thereof. More specific examples include tris(8-hydroxyquinoline) aluminum (Alq3 for short), anthracene, naphthalene, phenanthrene, pyrene, anthracene, perylene, butadiene, coumarin, C60, acridine, stilbene, 1,10-phenanthroline, derivatives thereof, and metal complexes thereof. In addition, an organic material having superior electron transport performance is preferably used. Specific examples of the organic material include an arylpyridine derivative and a benzimidazole derivative. For example, a total film thickness of the electron transport layer 15A and the electron injection layer 15B depends on the entire device configuration, but is preferably within a range of about 5 nm to about 200 nm both inclusive, and is more preferably within a range of about 10 nm to about 180 nm both inclusive.

The electron injection layer 15B enhances electron injection efficiency to the light-emitting layers of respective colors. Examples of a material of the electron injection layer 15B include alkali metal, alkali-earth metal, rare-earth metal and an oxide thereof, a complex oxide thereof, a fluoride thereof, and a carbonate thereof.

The second electrode 16 has, for example, a thickness of about 10 nm, and is configured of, for example, a single-layer film made of any one of conductive film materials having high light transmission properties including ITO, IZO, ZnO, InSnZnO, MgAg, Ag, and the like, or a laminate film made of two or more kinds selected from conductive film materials in the case where the display unit 1 is of a top emission type. In the case where the display unit 1 is of a bottom emission type, a high reflective material such as aluminum, AlSiC, titanium, or chromium is used.

### (Specific Configurations of Organic EL Devices 2R, 2G, and 2B)

In the embodiment, the organic EL devices 2R, 2G, and 2B, in particular, the organic EL devices 2G microscopically include the charge transport layer 17 which will be described later in addition to the above-described various functional layers.

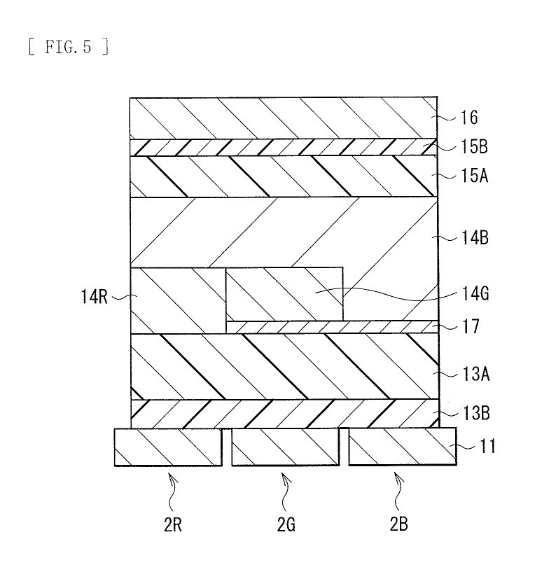

FIG. 5 schematically illustrates laminate configurations of the organic EL devices 2R, 2G, and 2B. As described above, in the organic EL devices 2R and 2G from among the organic EL devices 2R, 2G, and 2B, the red light-emitting layer 14R and the green light-emitting layer 14G are formed separately for each pixel. On the other hand, in the organic EL device 2B, the blue light-emitting layer 14B is so formed as to extend to a region where the organic EL devices 2R and 2G are formed. In other words, light-emitting layers of two colors (the red light-emitting layer 14R and the green light-emitting layer 14G) from among light-emitting layers of three colors are formed into a predetermined pattern (for example, a line pattern or a matrix pattern) on the drive substrate 11.

In the embodiment, the charge transport layer 17 is disposed on surfaces located closer to the first electrode 11 of the green light-emitting layer 14G and the blue light-emitting layer 14B from among the red light-emitting layer 14R, the green light-emitting layer 14G, and the blue light-emitting layer 14B (more specifically, between the green light-emitting layer 14G and the blue light-emitting layer 14B, and the hole transport layer 13A).

The charge transport layer 17 in this case includes a hole transport material, and has a thickness of, for example, about 5 nm to about 20 nm both inclusive. As the hole transport material, any one of the above-described materials of the hole transport layer 13A may used, but the hole transport material is not limited thereto. For example, in addition to the above-described materials of the hole transport layer 13A, a diaminodiphenyl derivative such as poly-TPD, or PPV or PEDOT-PSS used as a non-light-emissive hole transport material may be used. Moreover, the charge transport layer 17 and the hole transport layer 13A may be made of the same material as each other, or materials different from each other. The charge transport layer 17 is formed by the same pattern as that of the green light-emitting layer 14G after formation of the red light-emitting layer 14R.

### 1-2. Manufacturing Method

The above-describe display unit 1 is manufactured by the following processes, for example.

First, as illustrated in FIG. 6A, the first electrodes 11 are formed on the drive substrate 10. At this time, a film of the above-described electrode material is formed on an entire surface of the drive substrate 10 by, for example, a vacuum deposition method or a sputtering method, and then the film is patterned by etching with use of, for example, a photolithography method. Moreover, each of the first electrodes 11 is connected to the TFT 111 (more specifically, the source and drain electrodes 1106) through the contact hole H of the planarization layer 112 formed in the drive substrate 10.

Next, as illustrated in FIG. 6B, the insulating film 12 is formed. More specifically, the entire surface of the drive substrate 10 is coated with the above-described resin material by, for example, a spin coating method, and then an opening is formed in a part corresponding to each of the first electrodes 11 with use of, for example, a photolithography method. After the opening is formed, the insulating film 12 may be reflowed, if necessary.

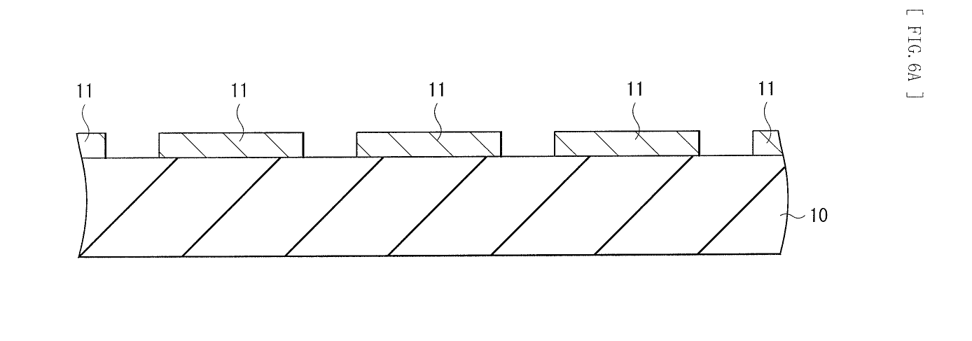

Then, as illustrated in FIG. 7, the hole injection layer 13B and the hole transport layer 13A are formed in this order by, for example, a vacuum deposition method to cover the first electrodes 11 and the insulating film 12. However, as a technique of forming the hole injection layer 13B and the hole transport layer 13A, in addition to the vacuum deposition method, a direct coating method such as a spin coating method, a slit coating method, or an ink jet method may be used, or a gravure offset method, a letterpress printing method, an intaglio reverse printing method, or the like may be used.

### (Process of Forming Light-Emitting Layers of G and R)

Next, as illustrated in FIG. 8, the red light-emitting layer 14R and the green light-emitting layer 14G are formed in a red pixel region 2R1 and a green pixel region 2G1, respectively. At this time, as will be described later, the green light-emitting layer 14G and the red light-emitting layer 14R are pattern-formed in this order by a reverse printing method with use of a blanket. Brief description is as follows.

1. Formation of first light-emitting layer

(1) Coat a blanket with a solution including a first light-emitting material

(2) Form a printing pattern on the blanket with use of an engraved plate

(3) Transfer the printing pattern on the blanket to the drive substrate 10

2. Formation of charge transport layer 17

(1) Coat a blanket with a solution including a hole transport material

(2) Form a printing pattern on the blanket with use of an engraved plate

(3) Transfer the printing pattern on the blanket to the drive substrate 10

3. Formation of second light-emitting layer

(1) Coat a blanket with a solution including a second light-emitting material

(2) Form a printing pattern on the blanket with use of an engraved plate

(3) Transfer the printing pattern on the blanket to the drive substrate 10

### 1. Formation of First Light-Emitting Layer

### (1) Process of Coating to Form First Light-Emitting Layer

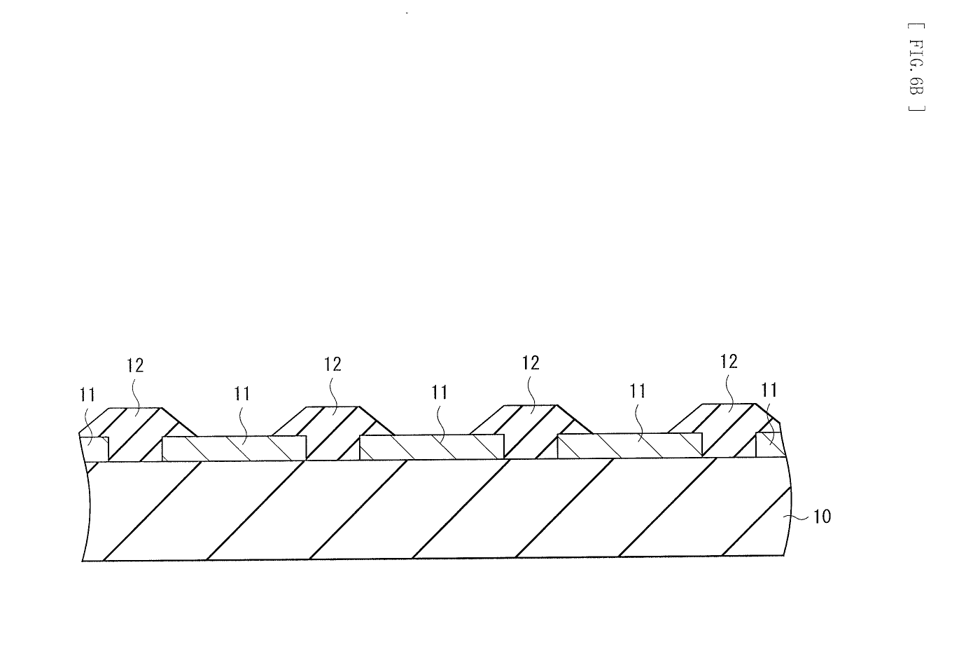

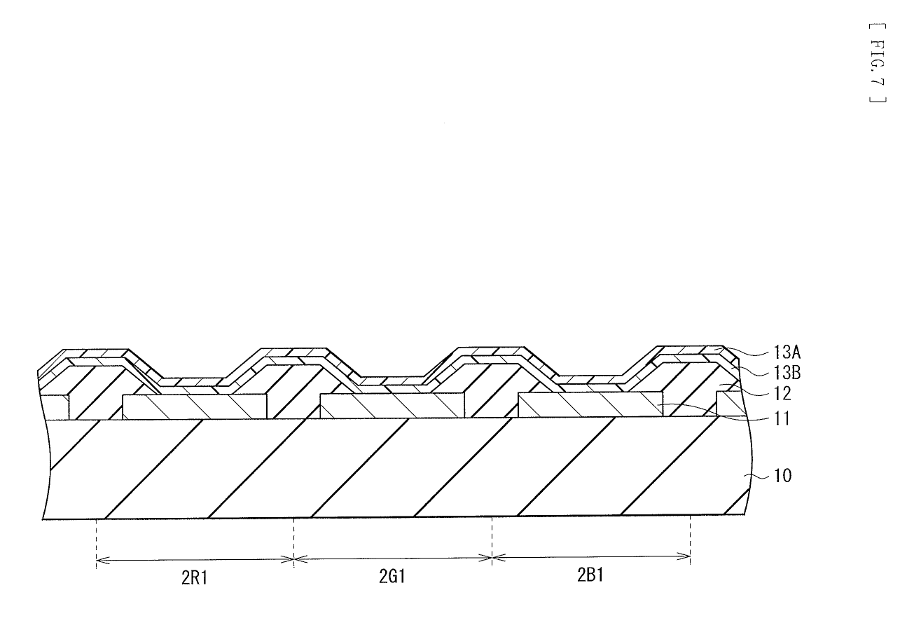

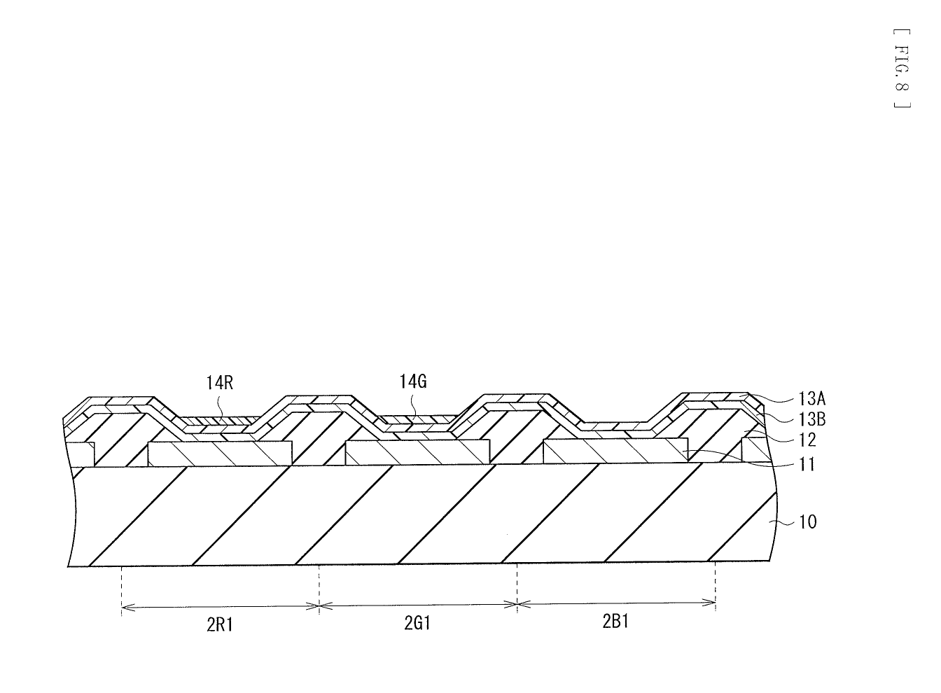

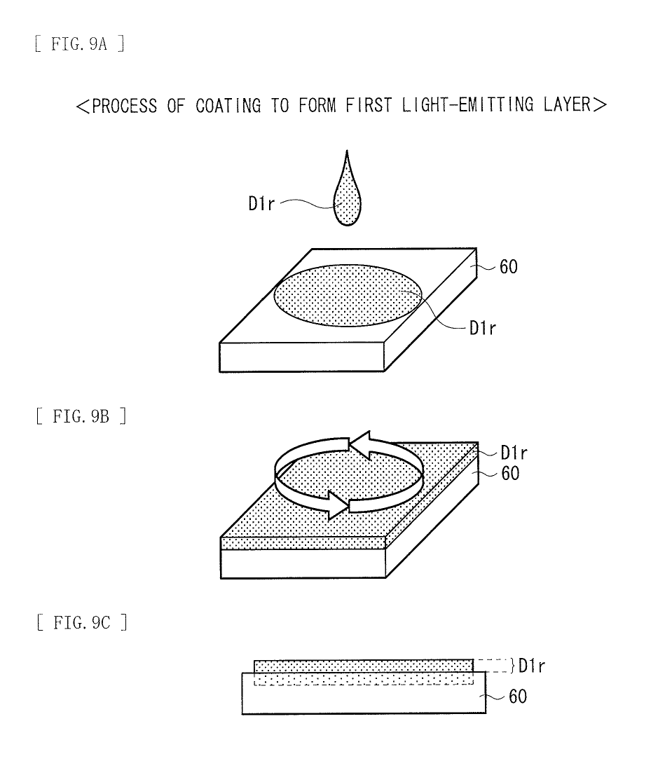

First, a blanket 60 used to transfer a first light-emitting layer (in this case, the red light-emitting layer 14R) is prepared, and the blanket 60 is coated with a solution D1r including a red light-emitting material. More specifically, as illustrated in FIGS. 9A and 9B, the solution D1r is dropped on the blanket 60, and an entire surface of the blanket 60 is coated with the solution D1r by a direct coating method such as a spin coating method or a slit coating method. Thus, as illustrated in FIG. 9C, a layer of the solution D1r including the red light-emitting material is formed on the blanket 60.

### (2) Process of Forming Printing Pattern

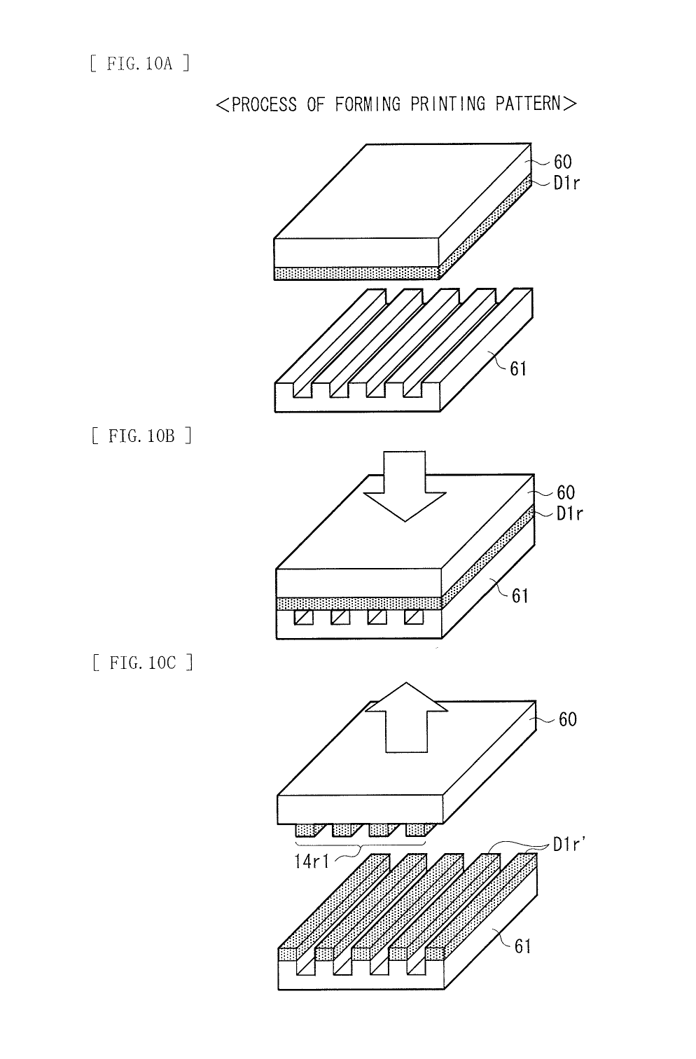

Next, a printing pattern layer (a printing pattern layer 14g1) of the red light-emitting layer 14R is formed on the blanket 60. More specifically, first, as illustrated in FIG. 10A, an engraved plate 61 having recessed portions corresponding to red pixel regions 2R1 and the layer of the solution D1r on the blanket 60 are so arranged as to face each other, and, as illustrated in FIG. 10B, the layer of the solution D1r on the blanket 60 is pressed against the engraved plate 61. After that, as illustrated in FIG. 10C, when the blanket 60 is separated from the engraved plate 61, unnecessary parts (D1r′) of the layer of the solution D1r are transferred to protruding portions of the engraved plate 61 to be removed from the blanket 60. Thus, a printing pattern 14r1 corresponding to red pixel regions of the red light-emitting layer 14R is formed on the blanket 60. It is to be noted that, in the drawings, a line pattern is illustrated; however, the shape of the pattern is not limited to the line pattern, as long as the pattern is consistent with a TFT pixel arrangement.

### (3) Transferring Process

Next, the printing pattern layer 14R1 of the red light-emitting layer 14R on the blanket 60 is transferred to the drive substrate 10. More specifically, as illustrated in FIG. 11A, the drive substrate 10 on which the hole injection layer 13B and the hole transport layer 13A have been already formed (hereinafter referred to as “drive substrate 10a” for convenience sake) and the blanket 60 are so arranged as to face each other. After that, the drive substrate 10a and the printing pattern 14r1 are aligned, and as illustrated in FIG. 11B, a surface where the printing pattern layer 14r1 is formed of the blanket 60 is pressed against the drive substrate 10a. Next, the blanket 60 is separated from the drive substrate 10a, and then the red light-emitting layer 14R is pattern-formed on the drive substrate 10a (refer to FIG. 11C).

### 2. Formation of Charge Transport Layer

### (1) Process of Coating to Form Charge Transport Layer

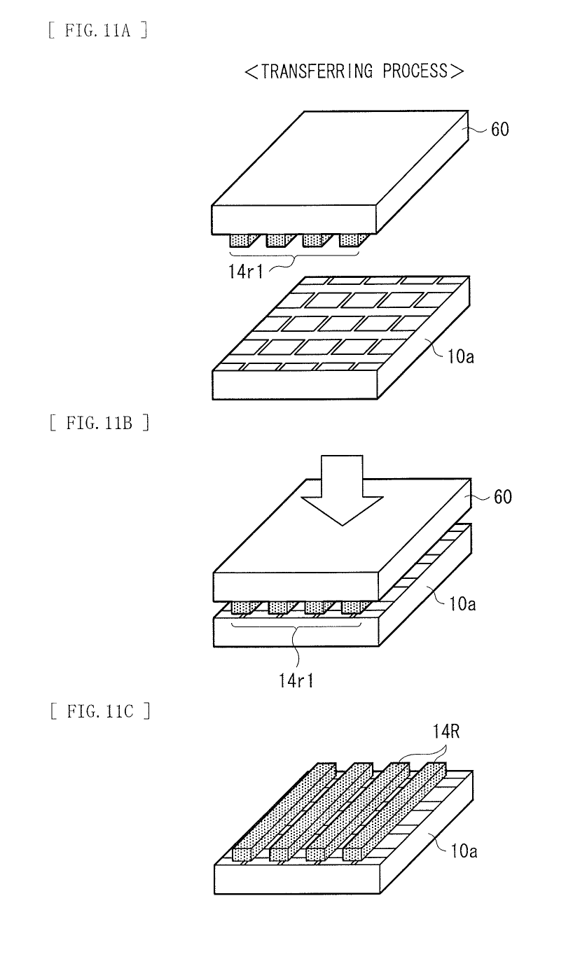

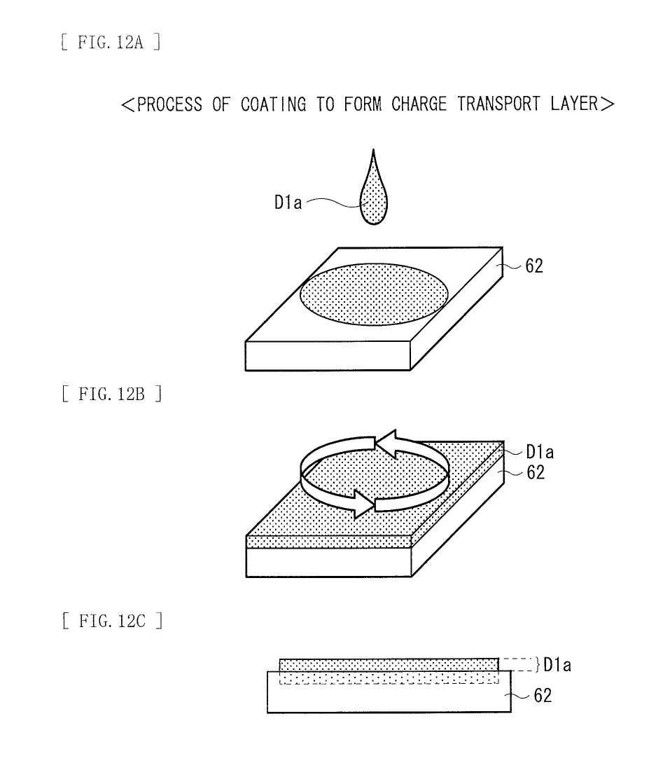

Next, a blanket 62 is coated with a solution D1a including a charge transport material, in this case, a hole transport material. More specifically, as illustrated in in FIGS. 12A and 12B, an entire surface of the blanket 62 is coated with the solution D1a including the hole transport material by, for example, a spin coating method. Thus, as illustrated in FIG. 12C, a layer of the solution D1a including the hole transport material is formed on the blanket 62.

### (2) Process of Forming Printing Pattern and (3) Transferring Process

Next, although not specifically illustrated, as in the case of the above-described red light-emitting layer 14R, a printing pattern layer of the charge transport layer 17 is formed on the blanket 62 with use of a predetermined engraved plate, and then is transferred to the drive substrate 10a. Thus, the charge transport layer 17 is formed on the drive substrate 10a.

### 3. Formation of Second Light-Emitting Layer

### (1) Process of Coating to Form Second Light-Emitting Layer

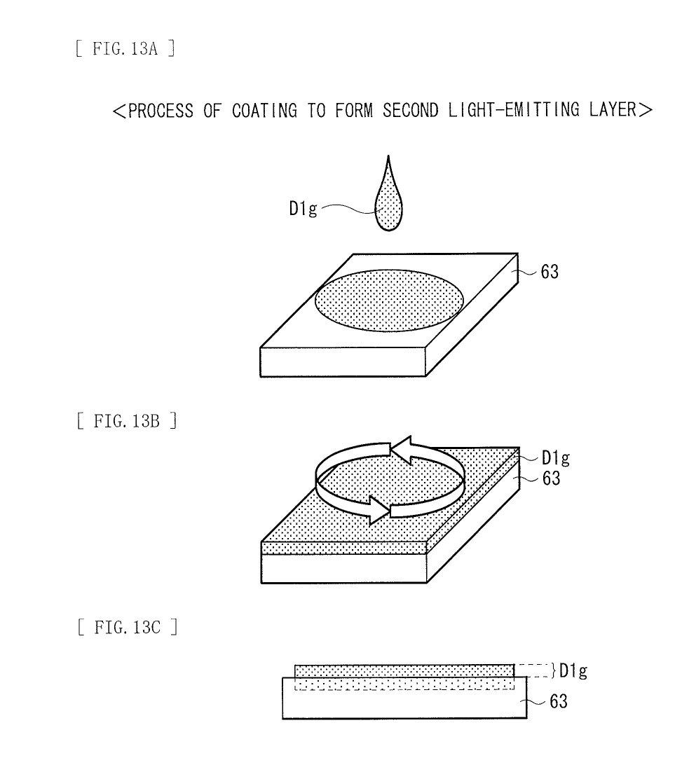

Next, a blanket 63 used to transfer a second light-emitting layer (in this case, the green light-emitting layer 14G) is prepared, and the blanket 63 is coated with a solution D1g including a green light-emitting material. More specifically, as illustrated in FIGS. 13A and 13B, the solution D1g is dropped on the blanket 63, and an entire surface of the blanket 63 is coated with the solution D1g by, for example, a direct coating method such as a spin coating method or a slit coating method. Thus, as illustrated in FIG. 13C, a layer of the solution D1g including the green light-emitting material is formed on the blanket 63.

### (2) Process of Forming Printing Pattern and (3) Transferring Process

Next, although not specifically illustrated, as in the case of the above-described red light-emitting layer 14R, a printing pattern layer of the green light-emitting layer 14G is formed on the blanket 62 with use of a predetermined engraved plate, and then is transferred to the drive substrate 10a. Thus, the green light-emitting layer 14G is formed on the drive substrate 10a.

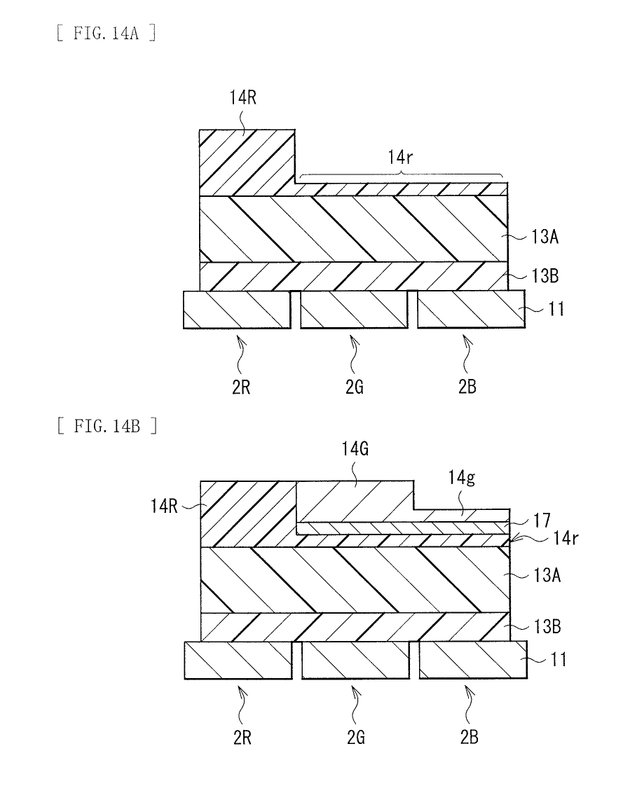

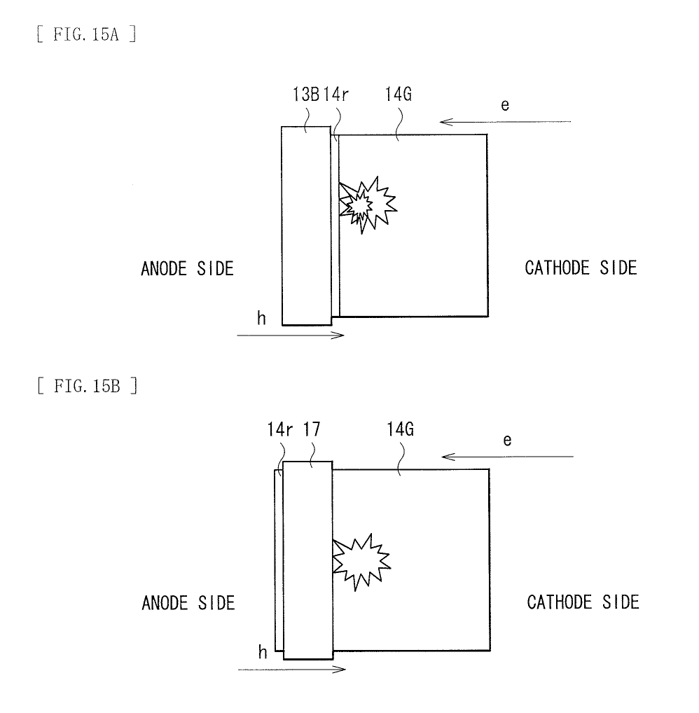

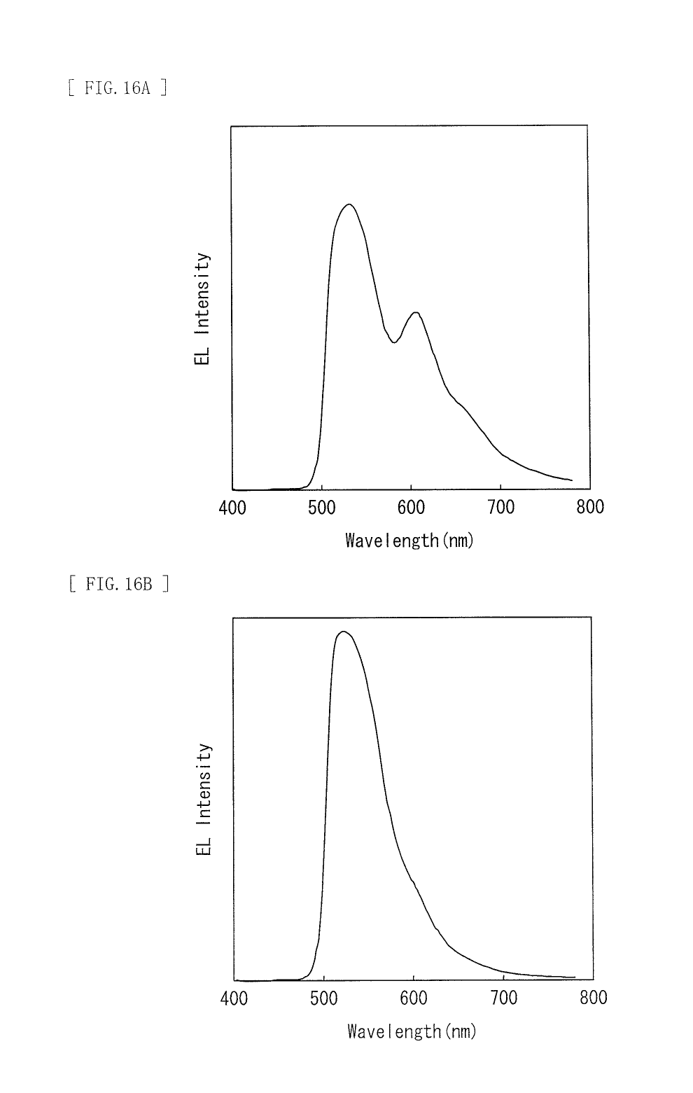

As described above, in the embodiment, patterns of the red light-emitting layer 14R and the green light-emitting layer 14G from among light-emitting layers of three colors are formed separately for each pixel by reverse printing with use of the blankets. At this time, for example, in a process of forming the red light-emitting layer 14R, the red light-emitting material absorbed when the blanket 60 is coated with the solution D1r remains on a region where the solution D1r is removed by the engraved plate 61 of the blanket 60. Therefore, in a process of transferring the red light-emitting layer 14R, as illustrated in FIG. 14A, the red light-emitting material (a red residue 14r) is adhered to a region other than the red pixel region 2R1, more specifically the green pixel region 2G1 and a blue pixel region 2B1. Therefore, as illustrated in FIG. 15A, in the green pixel region 2G 1, holes and electrons are transported from the first electrode 11 and the second electrode 16 by voltage application, and the green light-emitting layer 14G and the red light-emitting material located adjacent to the green light-emitting layer 14G are excited to emit light. As a result, as illustrated in FIG. 16A, emission light from the organic EL device 2G has not only a peak representing green light (around a wavelength of 550 nm) but also a peak representing red light (around a wavelength of 600 nm). In other words, green light and red light are mixed to cause a decline in color purity.

On the other hand, in the embodiment, as described above, the red light-emitting layer 14R is formed by reverse printing, and then the charge transport layer 17 is formed on the green pixel region 2G1 before formation of the green light-emitting layer 14G. In other words, as illustrated in FIG. 14B, the charge transport layer 17 is inserted between the red residue 14r on the green pixel region 2G1 and the green light-emitting layer 14G, and as illustrated in FIG. 15B, the red residue 14r is arranged outside of an exciton diffusion region. Therefore, the red light-emitting material does not emit light. As a result, emission light from the organic EL device 2G has only a peak representing green light (around a wavelength of 550 nm) as illustrated in FIG. 16B, and color purity is improved.

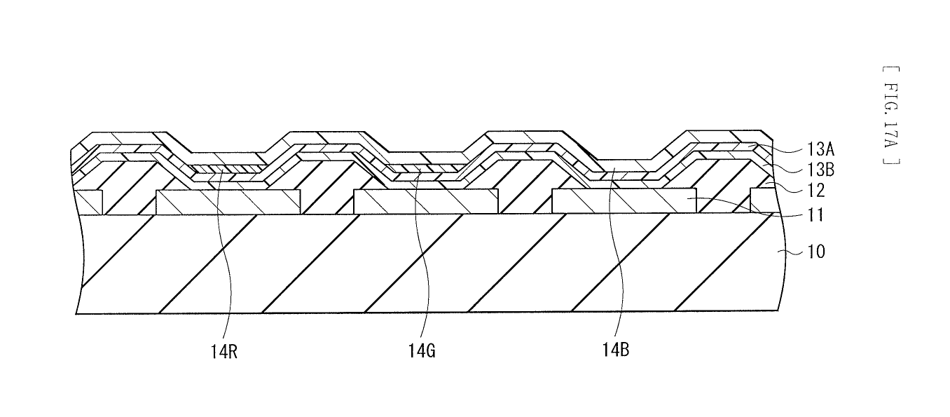

Next, as illustrated in FIG. 17A, the blue light-emitting layer 14B is formed on the entire surface of the drive substrate 10 by, for example, a vacuum deposition method. It is to be noted that, when the charge transport layer 17 is formed on the blue pixel region 2B 1 with a thickness of, for example, about 1 nm or over before formation of the blue light-emitting layer 14B, an improvement in device characteristics such as color purity of the blue organic EL device 2B is expected. Moreover, in this case, the blue light-emitting layer 14B is provided as a layer common to the organic EL devices 2R, 2G, and 2B; however, the blue light-emitting layer 14B is not limited thereto, and may be formed by reverse printing by a manner similar to that in the red light-emitting layer 14R and the green light-emitting layer 14G.

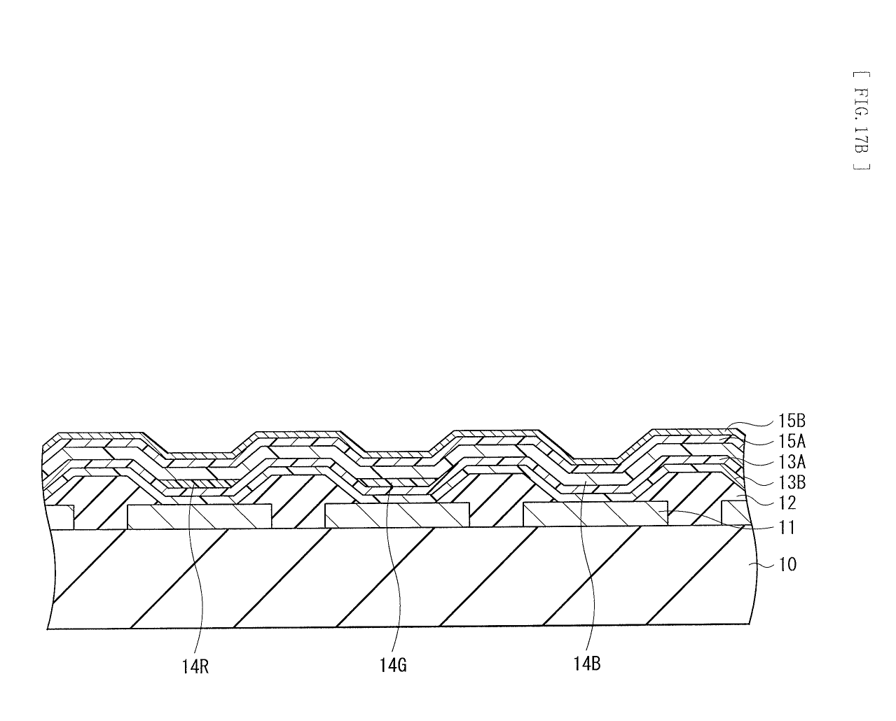

Then, as illustrated in FIG. 17B, the electron transport layer 15A and the electron injection layer 15B are formed on the blue light-emitting layer 14B by, for example, a vacuum deposition method. After that, as illustrated in FIG. 18, the second electrode 16 is formed on the electron injection layer 15B by, for example, a vacuum deposition method, a CVD method, or a sputtering method. Thus, the organic EL devices 2R, 2G, and 2B are formed on the drive substrate 10.

Finally, the protective layer 18 is so formed as to cover the organic EL devices 2R, 2G, and 2B on the drive substrate 10, and then the sealing substrate 20 is bonded to the drive substrate 10 with the adhesive layer 19 in between to complete the display unit 1 illustrated in FIG. 1.

### [Functions and Effects]

In the display unit 1 according to the embodiment, a scanning signal is supplied from the scanning line drive circuit 130 to each pixel through a gate electrode of the writing transistor Tr2, and an image signal supplied from the signal line drive circuit 120 through the writing transistor Tr2 is retained in the retention capacitor Cs. A drive current Id is thereby injected into each of the organic EL devices 2 to allow each of the organic EL devices 2 to emit light by the recombination of electrons and holes. In the case where the display unit 1 is of the top emission type, this light passes through the second electrode 16 and the sealing substrate 20 to be extracted toward a top of the display unit 1.

In such a display unit 1, in the manufacturing process, as described above, the light-emitting layers of two colors (the red light-emitting layer 14R and the green light-emitting layer 14G) from among the light-emitting layers of three colors R, G, and B are formed separately for each pixel by a reverse printing method with use of a blanket. The light-emitting layer of a first color (the first light-emitting layer, in this case, the red light-emitting layer 14R) from among the light-emitting layers of the three colors is formed, and then the charge transport layer 17 is formed on the organic EL devices of colors other than the first color (in this case, on the hole transport layer 13A of the green organic EL device 2G and the blue organic EL device 2B). After that, the light-emitting layer of a second color (the second light-emitting layer, in this case, the green light-emitting layer 14G) is formed.

### Comparative Example

In a display unit according to a comparative example relative to the embodiment, the light-emitting layer of the first color (for example, the red light-emitting layer) is formed by a reverse printing method with use of a blanket, and then the light-emitting layer of the second color (for example, the green light-emitting layer) is successively formed by reverse printing with use of a blanket as in the case of the light-emitting layer of the first color. In the case where the red light-emitting layer 14R and the green light-emitting layer 14G are successively formed, as described above, the red residue 14R including the red light-emitting material is formed on the hole transport layer 13A of the organic EL device 2G. The green light-emitting layer 14G formed subsequently is directly laminated on the red residue 14r. Therefore, the red residue 14r is exited together with the green light-emitting layer 14G by holes and electrons supplied from a hole supply layer (the hole injection layer and the hole transport layer) and an electron supply layer (the electron injection layer and the electron transport layer) to emit red light. As a result, in the organic EL device 2G, green light and red light are mixed to cause a decline in color purity.

On the other hand, in the embodiment, the red light-emitting layer 14R is formed, and then the charge transport layer 17 is formed on the green pixel region; therefore, in the organic EL device 2G, electron injection to the red residue 14r located on the hole transport layer 13A is suppressed by the charge transport layer 17. As a result, emission light from the organic EL device 2G includes only emission light from the green light-emitting layer 14G, and mixture of colors of emission spectra is suppressed to improve color purity.

As described above, in the display unit 1 according to the embodiment, a process of forming the charge transport layer 17 is inserted between processes of forming the first light-emitting layer (the red light-emitting layer 14R) and the second light-emitting layer (the green light-emitting layer 14G) with use of a reverse printing method, and the green light-emitting layer 14G is directly laminated on the charge transport layer 17. Thus, since the charge transport layer 17 is formed between the green light-emitting layer 14G and the red residue 14r formed on the green pixel region during formation of the red light-emitting layer 14R, the red residue 14r is arranged out of the exciton diffusion region. Accordingly, mixture of colors of emission spectra in the second organic EL device (the organic EL device 2G) is suppressed to improve color purity. In other words, device characteristics of the organic EL device 2G are improved, and a display unit with superior display quality is allowed to be provided.

Next, a second embodiment and a third embodiment will be described below. Like components are denoted by like numerals as of the above-described first embodiment and will not be further described.

### Second Embodiment

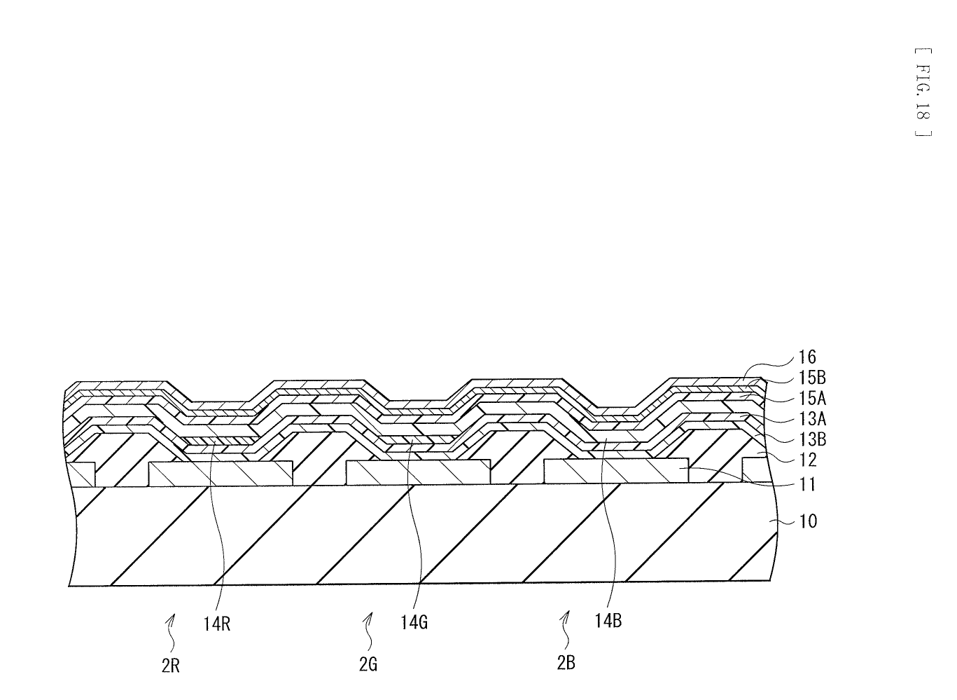

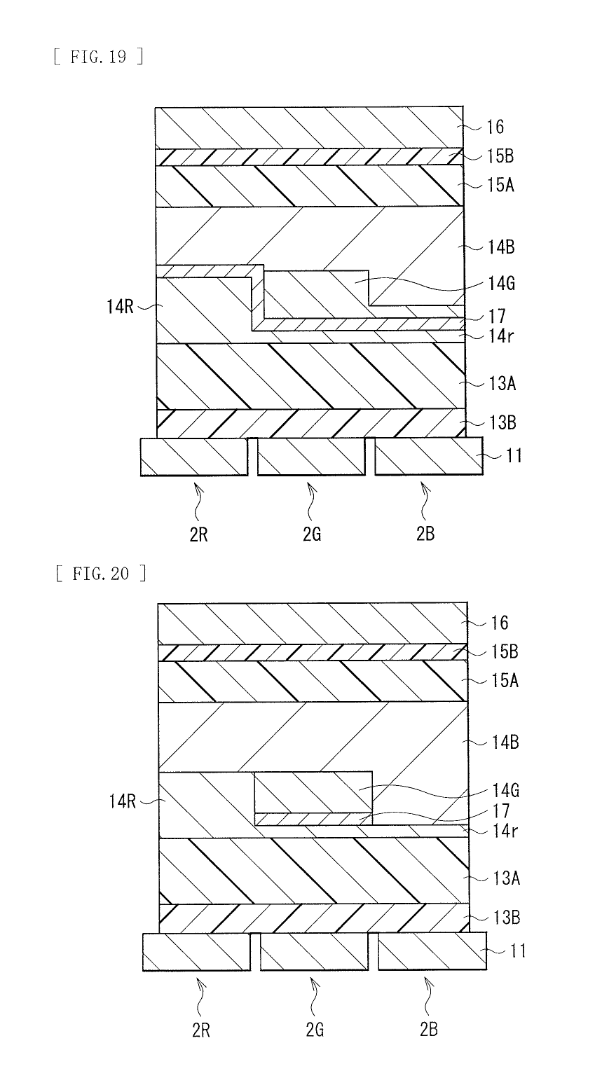

FIG. 19 schematically illustrates laminate configurations of the organic EL devices 2R, 2G, and 2B in a display unit 2 according to the second embodiment of the disclosure. The display unit 2 according to the present embodiment is different from the first embodiment in that the charge transport layer 17 is formed as a layer common to the organic EL devices 2R, 2G, and 2B. It is to be noted that, as with the above-described first embodiment, the organic EL devices 2R, 2G, and 2B are formed on the drive substrate 10 and are sealed by the protective layer 18, the adhesive layer 19, and the sealing substrate 20 to configure a display unit.

Also in the present embodiment, each of the organic EL devices 2R and 2G have, for example, a laminate configuration in which the hole injection layer 13B, the hole transport layer 13A, the red light-emitting layer 14R or the green light-emitting layer 14G, the blue light-emitting layer 14B, the electron transport layer 15A, the electron injection layer 15B, and the second electrode 16 are laminated in this order on the first electrode 1. Each of the organic EL devices 2B has, for example, a laminate configuration in which the hole injection layer 13B, the hole transport layer 13A, the blue light-emitting layer 14B, the electron transport layer 15A, the electron injection layer 15B, and the second electrode 16 are laminated in this order on the first electrode 11. Moreover, the red light-emitting layer 14R and the green light-emitting layer 14G are formed by reverse printing with use of a blanket, and the blue light-emitting layer 14B is formed by, for example, a vacuum deposition method.

In the embodiment, as described above, the charge transport layer 17 is formed as a layer common to the organic EL devices 2R, 2G, and 2B. More specifically, the charge transport layer 17 is continuously formed on the red light-emitting layers 14R of the organic EL devices 2R and the hole transport layers 13A of the organic EL devices 2G and 2B. After formation of the red light-emitting layer 14R with use of reverse printing, for example, area-coating is performed on a blanket, and then reverse printing is performed without patterning to form the charge transport layer 17.

Thus, in the embodiment, the first light-emitting layer (in this case, the red light-emitting layer 14R) is formed with use of a reverse printing method, and then the charge transport layer 17 as a common layer is formed on the red light-emitting layer 14R and the hole transport layer 13A of the organic EL devices 2G and 2B; therefore, in addition to the effects in the above-described embodiment, the use of the plate is reduced, thereby producing effects such as a reduction in cost by simplification of a manufacturing process, a reduction in component cost, and an improvement in manufacturing yield.

### Third Embodiment

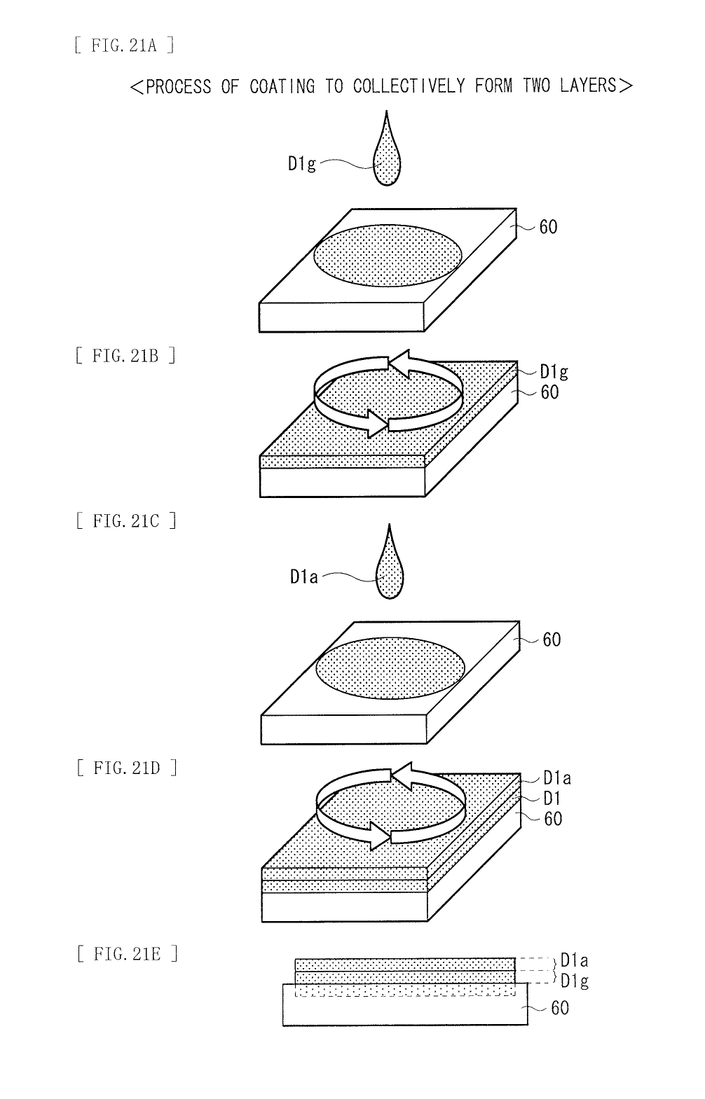

FIG. 20 schematically illustrates laminate configurations of the organic EL devices 2R, 2G, and 2B of a display unit 3 according to the third embodiment of the disclosure. FIGS. 21A to 21E illustrate a process of coating to collectively form a two layer, that is, the charge transport layer 17 and the green light-emitting layer 14G in the embodiment. The display unit 3 according to the embodiment is different from the above-described first embodiment in that the charge transport layer 17 and the green light-emitting layer 14G are collectively formed on the green pixel region 2G1 by coating.

In the present embodiment, as described above, the charge transport layer 17 and the green light-emitting layer 14G are collectively formed in this order on a part corresponding to the green pixel region of the hole transport layer 13A by coating. First, the red light-emitting layer 2R is formed by coating, and then the blanket 60 is coated with the solution D1g including a green light-emitting material. More specifically, as illustrated in FIGS. 21A and 21B, an entire surface of the blanket 60 is coated with the solution D1g including the green light-emitting material by, for example, a slit coating method to form a layer of the solution D1g. Next, as illustrated in FIGS. 21C and 21D, the entire surface of the blanket 60 is coated with a solution D1a including a charge transport material (in this case, a hole transport material) with the layer of the solution 1g in between by, for example, a slit coating method to form a layer of the solution D1a. Thus, as illustrated in FIG. 21E, a two-layer film including the layer of the solution D1g including the green light-emitting material and the layer of the solution D1a including the hole transport material are formed on the blanket 60. The two-layer film is patterned with use of, for example, a plate corresponding to the green pixel region 2G, and then is immediately transferred to the drive substrate 10a to form the charge transport layer 17 and the green light-emitting layer 14G on the green pixel region 2G.

Thus, in the embodiment, the first light-emitting layer (in this case, the red light-emitting layer 14R) is formed with use of a reverse printing method, and then the charge transport layer 17 and the second light-emitting layer (in this case, the green light-emitting layer 14G) are collectively formed. Therefore, the number of processes is reduced, compared to the above-described first embodiment, and the manufacturing process is allowed to be simplified. Moreover, contamination of siloxane derived from the blanket in an interface between the charge transport layer 17 and the second light-emitting layer is suppressed, and a deterioration in characteristics is preventable accordingly.

### (Modification)

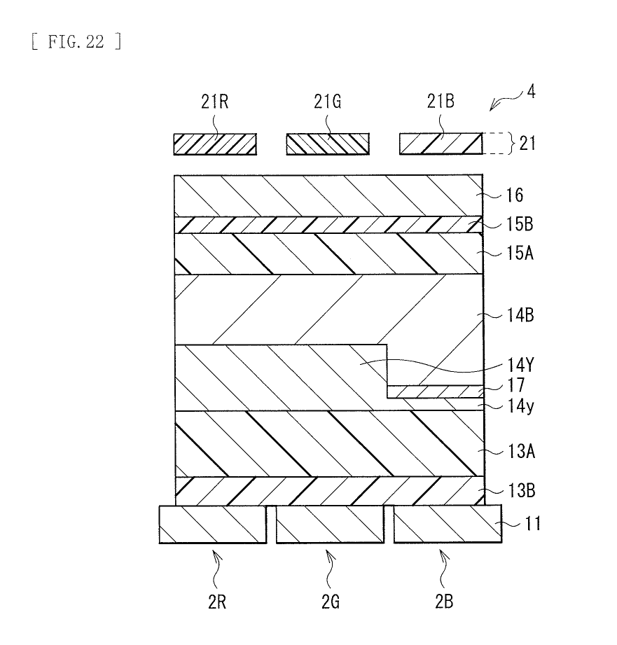

FIG. 22 schematically illustrates laminate configurations of the organic EL devices 2R, 2G, and 2B of a display unit 4 according to Modification 1. In the above-described first embodiment and the like, the red light-emitting layer and the green light-emitting layer are described as examples of light-emitting layers pattern-formed by reverse printing with use of a blanket; however, a light-emitting layer of any other color may be used. For example, in this modification, a yellow light-emitting layer 14Y may be formed over two pixels, that is, the organic EL devices 2R and 2G, and the blue light-emitting layer 14B may be formed to cover the yellow light-emitting layer 14Y. In this case, in the organic EL devices 2R and 2G, white light is produced by mixture of yellow and blue; therefore, a color filter layer 21 is provided on a side closer to the sealing substrate 20, and red light and green light are extracted with use of the color filter layer 21. The color filter layer 21 has red filters 21R, green filters 21G, and blue filters 21B facing the organic EL devices 2R, 2G, and 2B, respectively. The red filters 21R selectively allow red light to pass therethrough, the green filters 21G selectively allow green light to pass therethrough, and the blue filters 21B selectively allow and blue light to pass therethrough. With such a configuration, in this modification, the charge transport layer 17 is formed between a part corresponding to the blue pixel of the blue light-emitting layer 14B and the hole transport layer 13A.

In this modification, the yellow light-emitting layer 14Y is formed on a region corresponding to two pixels, that is, the red pixel and the green pixel on the hole transport layer 13A by reverse printing with use of a blanket, and then the charge transport layer 17 is formed on a region corresponding to the blue pixel. After that, the blue light-emitting layer 14B is formed on the charge transport layer 17. Therefore, electron injection to a yellow residue 14y located on the hole transport layer 13A is suppressed, and mixture of colors of emission spectra in the blue pixel is suppressed.

### Application Examples

The display units 1 to 4 each including the organic EL devices 2R, 2G, and 2B described in the above-described first to third embodiments and the above-described Modification 1 are incorporated into the following electronic apparatuses displaying an image in various fields.

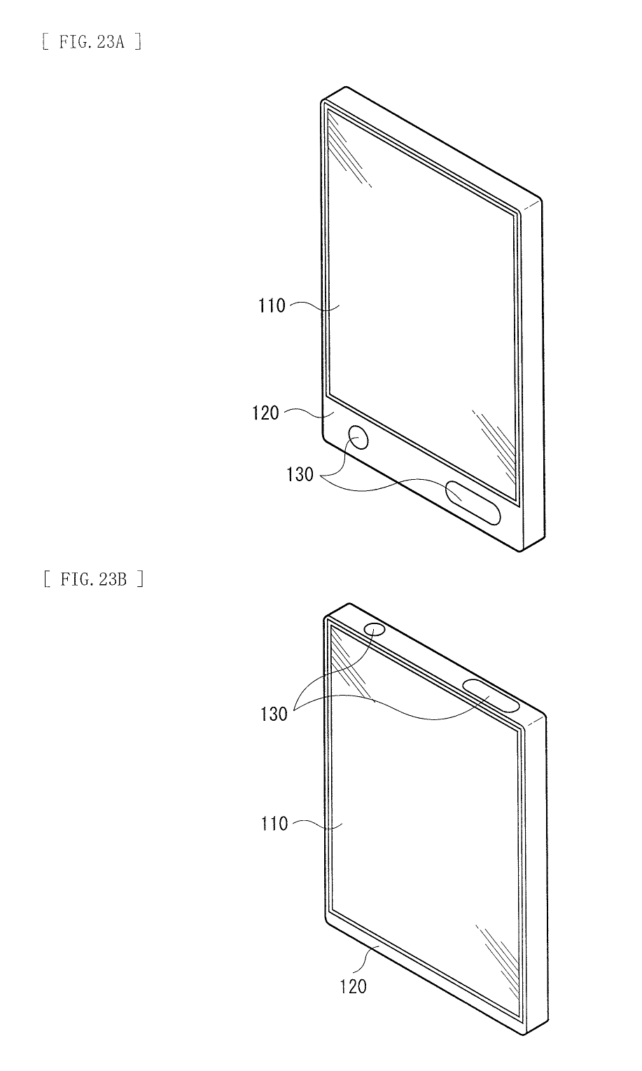

FIGS. 23A and 23B illustrate an appearance of a smartphone. The smartphone includes, for example, a display section 110 (the display unit 1 or the like) and a non-display section (an enclosure) 120, and an operation section 130. The operation section 130 may be disposed on a front surface of the non-display section 120, as illustrated in FIG. 23A, or may be disposed on a top surface of the non-display section 120, as illustrated in FIG. 23B.

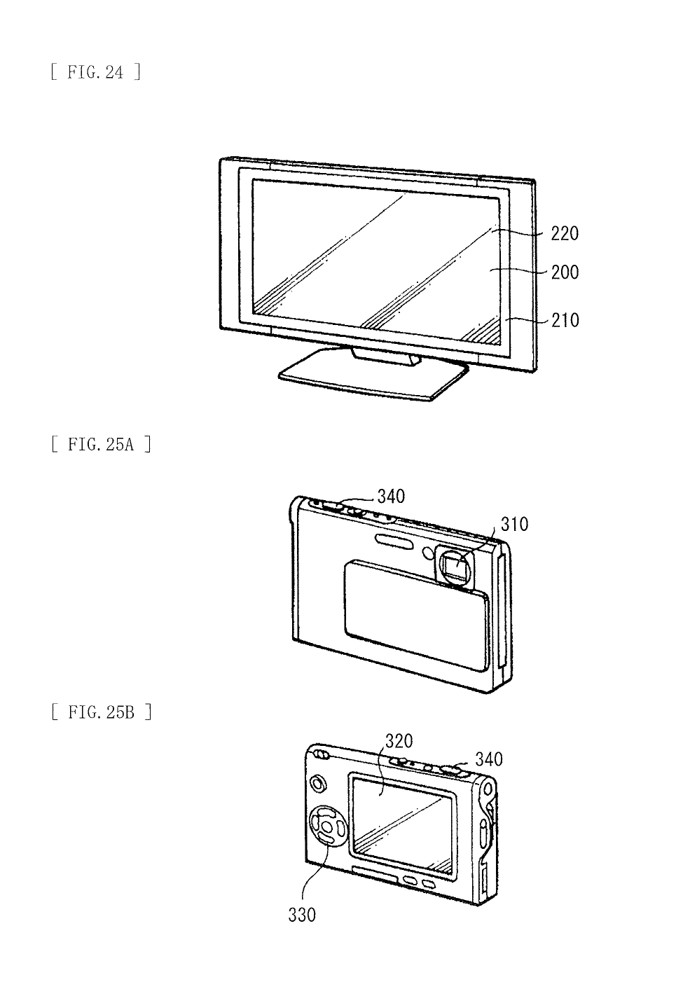

FIG. 24 illustrates an appearance configuration of a television. The television includes, for example, an image display screen section 200 (the display unit 1 or the like) including a front panel 210 and a filter glass 220.

FIGS. 25A and 25B illustrate appearance configurations on a front side and a back side, respectively, of a digital still camera. The digital still camera includes, for example, a light-emitting section 310 for a flash, a display section 320 (the display unit 1 or the like), a menu switch 330, and a shutter button 340.

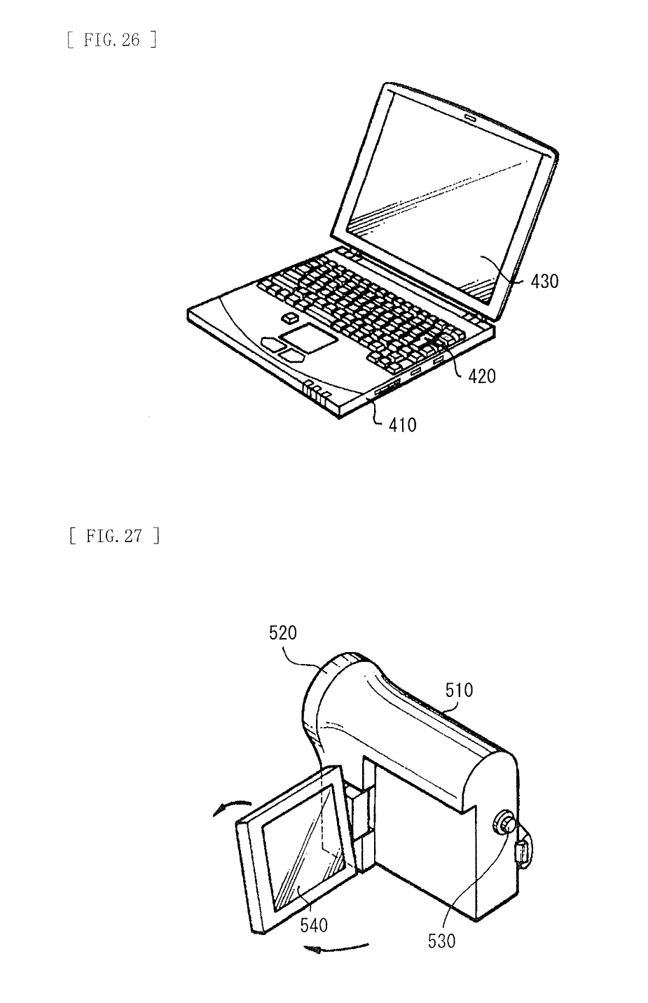

FIG. 26 illustrates an appearance configuration of a notebook personal computer. The notebook personal computer includes, for example, a main body 410, a keyboard 420 for operation of inputting characters and the like, and a display section 430 (the display unit 1 or the like) for displaying an image.

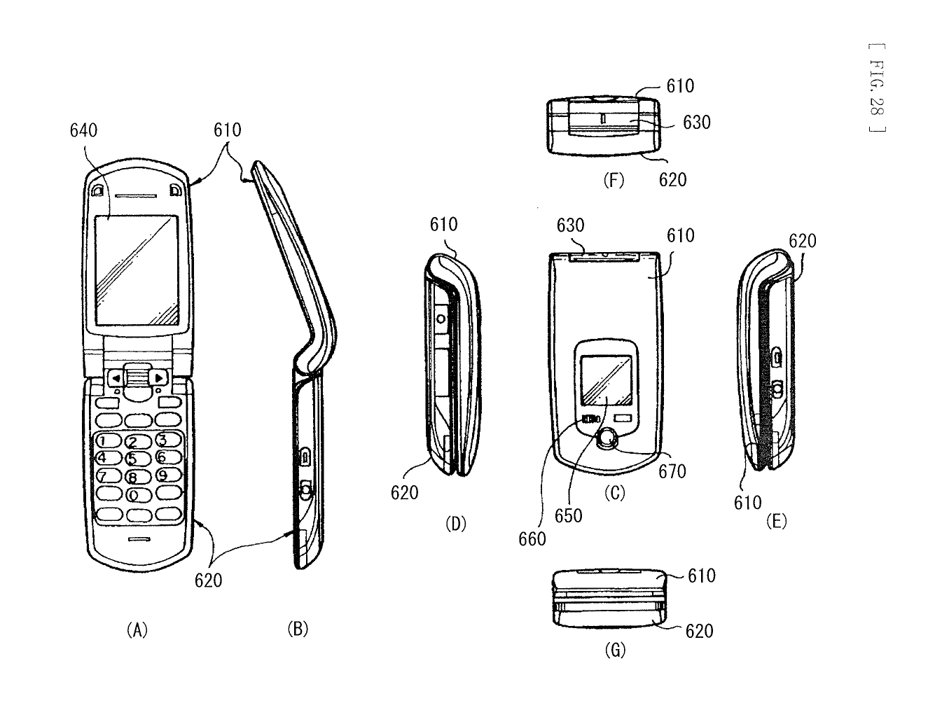

FIG. 27 illustrates an appearance configuration of a video camera. The video camera includes, for example, a main body 510, a lens 520 provided on a front surface of the main body 510 and for shooting an image of an object, a shooting start/stop switch 530, and a display section 560 (the display unit 1 or the like).

FIG. 28 illustrates appearance configurations of a cellular phone. Parts (A) and (B) in FIG. 28 are a front view and a side view in a state in which the cellular phone is opened, respectively, and parts (C), (D), (E), (F), and (G) in FIG. 28 are a front view, a left side view, a right side view, a top view, and a bottom view in a state in which the cellular phone is closed, respectively. The cellular phone has a configuration in which, for example, a top-side enclosure 610 and a bottom-side enclosure 620 are connected together through a connection section (hinge section) 630, and the cellular phone includes a display 640 (the display unit 1 or the like), a sub-display 650, a picture light 660, and a camera 670.

Although the present disclosure is described refereeing to the first to third embodiments and the modification, the disclosure is not limited thereto, and may be variously modified. For example, in the above-described embodiments and the like, the red light-emitting layer and the green light-emitting layer are formed as the first light-emitting layer which is first formed by a reverse printing method and the second light layer subsequently formed by a reverse printing method, respectively; however, the light-emitting layers of respective colors may be formed in reverse order.

Moreover, as the charge transport material in the disclosure, an appropriate hole transport material or an appropriate electron transport material may be selected, depending on the order of formation of light-emitting layers or device characteristics in each pixel.

Further, the material and thickness of each layer, the method and conditions of forming each layer are not limited to those described in the above-described embodiments and the like, and each layer may be made of any other material with any other thickness by any other method under any other conditions. In addition, it is not necessary to include all of the layers described in the above-described embodiments and the like, and any of the layers may be removed as appropriate. Further, a layer other than the layers described in the above-described embodiments and the like may be further included. For example, one or more layers made of a material having hole transport performance such as a common hole transport layer described in Japanese Unexamined Patent Application Publication No. 2011-233855 may be further included between the charge transport layer 17 and the blue light-emitting layer 14B of the blue EL device 2B. When such a layer is further included, light emission efficiency and life characteristics are improved.

It is to be noted that the technology is allowed to have the following configurations.

(1) An organic electroluminescence unit including:

a plurality of light-emitting layers of different colors;

a first electrode and a second electrode applying a voltage to each of the plurality of light-emitting layers; and

a charge transport layer disposed between one or more light-emitting layers of the plurality of light-emitting layers and the first electrode.

(2) The organic electroluminescence unit according to (1), in which

the plurality of light-emitting layers include a first light-emitting layer and a second light-emitting layer separately for each pixel, and

the charge transport layer is formed on a side closer to the first electrode of the second light-emitting layer of the first and second light-emitting layers.

(3) The organic electroluminescence unit according to (2), in which the charge transport layer is continuously disposed on a side closer to the second electrode of the first light-emitting layer and a side closer to the first electrode of the second light-emitting layer.

(4) The organic electroluminescence unit according to (2) or (3), further including a red pixel, a green pixel, and a blue pixel,

in which a red light-emitting layer is formed as the first light-emitting layer in the red pixel, and a green light-emitting layer is formed as the second light-emitting layer in the green pixel.

(5) The organic electroluminescence unit according to any one of (2) to (4), further including a red pixel, a green pixel, and a blue pixel,

in which a green light-emitting layer is formed as the first light-emitting layer in the green pixel, and a red light-emitting layer is formed as the second light-emitting layer in the red pixel.

(6) The organic electroluminescence unit according to (4) or (5), in which

the blue pixel includes a blue light-emitting layer, and

the charge transport layer is also disposed on a side closer to the first electrode of the blue light-emitting layer in the blue pixel.

(7) The organic electroluminescence unit according to any one of (2) to (6), further including a red pixel, a green pixel, and a blue pixel,

in which a yellow light-emitting layer is included in the red pixel and the green pixel, and

a blue light-emitting layer is included in the blue pixel.

(8) The organic electroluminescence unit according to (7), in which the charge transport layer is formed on a side closer to the first electrode of the blue light-emitting layer in the blue pixel.

(9) The organic electroluminescence unit according to (7) or (8), in which the blue light-emitting layer is so formed as to extend to regions on the red light-emitting layer and the green light-emitting layer.

(10) The organic electroluminescence unit according to any one of (1) to (9), in which the charge transport layer is made of a hole transport material.

(11) The organic electroluminescence unit according to any one of (2) to (10), in which the first light-emitting layer includes siloxane.

(12) A method of manufacturing an organic electroluminescence unit including:

forming a first electrode;

forming a plurality of light-emitting layers of different colors on the first electrode; and

forming a second electrode on the plurality of light-emitting layers,

in which in the forming of the light-emitting layers, one of the plurality of light-emitting layers is formed, and then a charge transport layer is formed between one or more other light-emitting layers and the first electrode.

(13) The method of manufacturing the organic electroluminescence unit according to (12), in which

in the forming of the light-emitting layers, a first light-emitting layer and a second light-emitting layer are formed in this order by printing with use of one or two kinds of plates, and

the charge transport layer is formed with use of a plate for forming the second light-emitting layer after the forming of the first light-emitting layer.

(14) The method of manufacturing the organic electroluminescence unit according to (13), in which

the second light-emitting layer and the charge transport layer are formed in a laminate form after the forming of the first light-emitting layer.

(15) The method of manufacturing the organic electroluminescence unit according to (13) or (14), in which a red light-emitting layer is formed as the first light-emitting layer in a red pixel region, and a green light-emitting layer is formed as the second light-emitting layer in a green pixel region.

(16) The method of manufacturing the organic electroluminescence unit according to (15), in which the red light-emitting layer and the green light-emitting layer are formed, and then a blue light-emitting layer is formed from regions on the red light-emitting layer and the green light-emitting layer to a blue pixel region.

(17) The method of manufacturing the organic electroluminescence unit according to any one of (12) to (16), in which a yellow light-emitting layer is formed as the first light-emitting layer in a red pixel region and a green pixel region, and a blue light-emitting layer is formed as the second light-emitting layer in a blue pixel region.

(18) The method of manufacturing the organic electroluminescence unit according to any one of (12) to (17), in which the plurality of light-emitting layers and the charge transport layer are formed by a plate printing method.

(19) The method of manufacturing the organic electroluminescence unit according to any one of (12) to (18), in which the plurality of light-emitting layers and the charge transport layer are formed by a reverse offset printing method.

(20) An electronic apparatus including an organic electroluminescence unit, the organic electroluminescence unit including:

a plurality of light-emitting layers of different colors;

a first electrode and a second electrode applying a voltage to each of the plurality of light-emitting layers; and

a charge transport layer disposed between one or more light-emitting layers of the plurality of light-emitting layers and the first electrode.

The present disclosure contains subject matter related to that disclosed in Japanese Priority Patent Application No. 2012-097626 filed in the Japan Patent Office on Apr. 23, 2012, the entire content of which is hereby incorporated by reference.

It should be understood by those skilled in the art that various modifications, combinations, sub-combinations, and alterations may occur depending on design requirements and other factors insofar as they are within the scope of the appended claims or the equivalents thereof.

1. An organic electroluminescence unit comprising:
a plurality of light-emitting layers of different colors;
a first electrode and a second electrode applying a voltage to each of the plurality of light-emitting layers; and
a charge transport layer disposed between one or more light-emitting layers of the plurality of light-emitting layers and the first electrode.

2. The organic electroluminescence unit according to claim 1, wherein
the plurality of light-emitting layers include a first light-emitting layer and a second light-emitting layer separately for each pixel, and
the charge transport layer is formed on a side closer to the first electrode of the second light-emitting layer of the first and second light-emitting layers.

3. The organic electroluminescence unit according to claim 2, wherein the charge transport layer is continuously disposed on a side closer to the second electrode of the first light-emitting layer and a side closer to the first electrode of the second light-emitting layer.

4. The organic electroluminescence unit according to claim 2, further including a red pixel, a green pixel, and a blue pixel,
wherein a red light-emitting layer is formed as the first light-emitting layer in the red pixel, and a green light-emitting layer is formed as the second light-emitting layer in the green pixel.

5. The organic electroluminescence unit according to claim 2, further including a red pixel, a green pixel, and a blue pixel,
wherein a green light-emitting layer is formed as the first light-emitting layer in the green pixel, and a red light-emitting layer is formed as the second light-emitting layer in the red pixel.

6. The organic electroluminescence unit according to claim 4, wherein
the blue pixel includes a blue light-emitting layer, and
the charge transport layer is also disposed on a side closer to the first electrode of the blue light-emitting layer in the blue pixel.

7. The organic electroluminescence unit according to claim 2, further comprising a red pixel, a green pixel, and a blue pixel,
wherein a yellow light-emitting layer is included in the red pixel and the green pixel, and
a blue light-emitting layer is included in the blue pixel.

8. The organic electroluminescence unit according to claim 7, wherein the charge transport layer is formed on a side closer to the first electrode of the blue light-emitting layer in the blue pixel.

9. The organic electroluminescence unit according to claim 7, wherein the blue light-emitting layer is so formed as to extend to regions on the red light-emitting layer and the green light-emitting layer.

10. The organic electroluminescence unit according to claim 1, wherein the charge transport layer is made of a hole transport material.

11. The organic electroluminescence unit according to claim 2, wherein the first light-emitting layer includes siloxane.

12. A method of manufacturing an organic electroluminescence unit comprising:
forming a first electrode;
forming a plurality of light-emitting layers of different colors on the first electrode; and
forming a second electrode on the plurality of light-emitting layers,
wherein in the forming of the light-emitting layers, one of the plurality of light-emitting layers is formed, and then a charge transport layer is formed between one or more other light-emitting layers and the first electrode.

13. The method of manufacturing the organic electroluminescence unit according to claim 12, wherein
in the forming of the light-emitting layers, a first light-emitting layer and a second light-emitting layer are formed in this order by printing with use of one or two kinds of plates, and
the charge transport layer is formed with use of a plate for forming the second light-emitting layer after the forming of the first light-emitting layer.

14. The method of manufacturing the organic electroluminescence unit according to claim 13, wherein
the second light-emitting layer and the charge transport layer are formed in a laminate form after the forming of the first light-emitting layer.

15. The method of manufacturing the organic electroluminescence unit according to claim 14, wherein a red light-emitting layer is formed as the first light-emitting layer in a red pixel region, and a green light-emitting layer is formed as the second light-emitting layer in a green pixel region.

16. The method of manufacturing the organic electroluminescence unit according to claim 15, wherein the red light-emitting layer and the green light-emitting layer are formed, and then a blue light-emitting layer is formed from regions on the red light-emitting layer and the green light-emitting layer to a blue pixel region.

17. The method of manufacturing the organic electroluminescence unit according to claim 12, wherein a yellow light-emitting layer is formed as the first light-emitting layer in a red pixel region and a green pixel region, and a blue light-emitting layer is formed as the second light-emitting layer in a blue pixel region.

18. The method of manufacturing the organic electroluminescence unit according to claim 12, wherein the plurality of light-emitting layers and the charge transport layer are formed by a plate printing method.

19. The method of manufacturing the organic electroluminescence unit according to claim 12, wherein the plurality of light-emitting layers and the charge transport layer are formed by a reverse offset printing method.

20. An electronic apparatus including an organic electroluminescence unit, the organic electroluminescence unit comprising:
a plurality of light-emitting layers of different colors;
a first electrode and a second electrode applying a voltage to each of the plurality of light-emitting layers; and
a charge transport layer disposed between one or more light-emitting layers of the plurality of light-emitting layers and the first electrode.
